(19) United States
(12) Patent Application Publication
(10) Pub. No.: US 2025/0112165 A1
(43) Pub. Date: Apr. 3, 2025

(54) ANISOTROPIC CONDUCTIVE CONNECTIONS FOR INTERCONNECT BRIDGES AND RELATED METHODS

(71) Applicant: Intel Corporation, Santa Clara, CA (US)

(72) Inventors: Brandon Marin, Gilbert, AZ (US); Hiroki Tanaka, Gilbert, AZ (US); Robert May, Chandler, AZ (US); Srinivas Pietambaram, Chandler, AZ (US); Gang Duan, Chandler, AZ (US); Suddhasattwa Nad, Chandler, AZ (US); Numair Ahmed, Chandler, AZ (US); Jeremy Ecton, Gilbert, AZ (US); Benjamin Taylor Duong, Phoenix, AZ (US); Bai Nie, Chandler, AZ (US); Haobo Chen, Chandler, AZ (US); Xiao Liu, Chandler, AZ (US); Bohan Shan, Chandler, AZ (US); Shruti Sharma, Chandler, AZ (US); Mollie Stewart, Lake Oswego, OR (US)

(21) Appl. No.: 18/478,250

(22) Filed: Sep. 29, 2023

(51) Int. Cl. H01L 23/538; H01L 21/48; H01L 23/00

(52) U.S. Cl. CPC H01L 23/5385; H01L 21/4857; H01L 24/29; H01L 24/32; H01L 24/83; H01L 24/16; H01L 24/17; H01L 2224/16227; H01L 2224/1703; H01L 2224/29006; H01L 2224/29028; H01L 2224/2929; H01L 2224/29324; H01L 2224/29339; H01L 2224/29344; H01L 2224/29347; H01L 2224/29355; H01L 2224/29388; H01L 2224/2939; H01L 2224/29393; H01L 2224/29439; H01L 2224/29444; H01L 2224/29455; H01L 2224/29488; H01L 2224/2949; H01L 2224/32227; H01L 2224/83191; H01L 2224/83192; H01L 2224/83201; H01L 2224/83851; H01L 2224/83862; H01L 2924/01006; H01L 2924/0132; H01L 2924/0615

(57) ABSTRACT

Anisotropic conductive connections for interconnect bridges and related methods are disclosed herein. An example a package substrate for an integrated circuit package, the package substrate comprising a first pad disposed at a first end of an interconnect within the package substrate, the first pad disposed in a cavity in the package substrate, an interconnect bridge disposed in the cavity, the interconnect bridge including a second pad, and a third pad, and a layer disposed between the first pad and the second pad, the layer having a first conductivity between the first pad and the second pad, the layer having a second conductivity between the second pad and the third pad, the first conductivity greater than the second conductivity.

### FIELD OF THE DISCLOSURE

This disclosure relates generally to integrated circuit packages and, more particularly, to anisotropic conductive connections for interconnect bridges and related methods.

### BACKGROUND

Integrated circuit (IC) chips and/or semiconductor dies are routinely connected to larger circuit boards such as motherboards and other types of printed circuit boards (PCBs) via a package substrate. Integrated circuit (IC) chips and/or dice (e.g., dies, etc.) have exhibited reductions in size and increases in interconnect densities as technology has advanced.

### BRIEF DESCRIPTION OF THE DRAWINGS

FIG. 1 illustrates an example integrated circuit (IC) package on a printed circuit board.

FIG. 2 is a cross-sectional view of a package substrate of FIG. 1 including an interconnect bridge implemented in accordance with teachings of this disclosure.

FIG. 3A is another cross-section view of an assembly including the interconnect bridge disposed within a cavity implemented in accordance with teachings of this disclosure.

FIG. 3B is another cross-section view of another assembly including an interconnect bridge disposed within a cavity including a passivation layer implemented in accordance with teachings of this disclosure.

FIG. 4A is a cross-section view of the interconnect bridge of FIG. 2 including an anisotropic connection layer before particle sorting.

FIG. 4B is a cross-section view of the integrated die of FIG. 4A coupled to a die within the cavity of the package substrate after particle sorting.

FIGS. 5A and 5B are schematic views of example conductive particles that can be used in the anisotropic connection layer of FIGS. 3A-4B.

FIGS. 6A-6L are cross-section views depicting the assembly of FIG. 3B at various stages of manufacturing.

FIG. 7 is a flowchart of an example manufacturing process for the assembly of FIG. 3B.

FIG. 8 is a cross-sectional view that depicts alternative manufacturing stages that can be used to manufacture the package substrate of FIG. 3B.

FIG. 9 is a flowchart of another example manufacturing process for manufacturing the interconnect bridge of FIG. 3B.

FIGS. 10A-10C are cross-sectional views depicting the interconnect bridge of FIG. 3B at various stages of manufacturing.

FIG. 11 is a flowchart of an example manufacturing process for the interconnect bridge of FIG. 3B.

FIG. 12 is cross-section views depicting an alternative interconnect bridge including an anisotropic layer implemented in accordance with teachings of this disclosure.

FIG. 13 is a top view of a wafer and dies that may be included in an IC package constructed in accordance with teachings disclosed herein.

FIG. 14 is a cross-sectional side view of an IC device that may be included in an IC package constructed in accordance with teachings disclosed herein.

FIG. 15 is a cross-sectional side view of an IC device assembly that may include an IC package constructed in accordance with teachings disclosed herein.

FIG. 16 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Interconnect bridges can be used to connect dies coupled to a package substrate. Such interconnect bridges are disposed within cavities of the package substrate and provide features that enable electrical coupling of dies thereto. Interconnect bridges include and/or correspond to semiconductor dies that include compute components, which increase the processing density of integrated circuits including such interconnect bridges. In some examples, the computer components within interconnect bridges are passive and do not include active semiconductor devices (e.g., transistors). For instance, in some examples, an interconnect bridge contains electrical routing (e.g., traces and connecting vias) fabricated on a semiconductor wafer) without any active components. In other examples, interconnect bridges may include at least some active components. While interconnect bridges increase the processing density of integrated circuits, this processing density offered by interconnect bridges increases power consumption. To compensate for such increased power consumption, some interconnect bridges can be connected to the power source of the integrated circuit packages by one or more vias, such as through silicon vias (TSVs), which extend through the base semiconductor material of the interconnect bridges. Such interconnect bridges can include contact pads on an exterior surface of the interconnect bridges that are electrically coupled to the vias. These contact pads serve to electrical couple the interconnect bridge to electrical interconnects (e.g., electrical routing) within the package substrate. Techniques for electrically coupling interconnect bridges to the package substrate, such as thermal compression bonding (TCB) using conventional solder materials, can result in faults in the connection between the interconnect bridge and the package substrate. For example, prior TCB techniques can result in tin wicking, misalignment between the contact pads on the interconnect bridge and corresponding contacts on the package substrate, and underfill voids. In some examples, these faults can degrade the effectiveness of the coupling between the interconnect bridge and the power source of the integrated circuitry package.

Examples disclosed herein reduce the likelihood of coupling faults between interconnect bridges and package substrates and include anisotropic conductive layers disposed between the interconnect bridges and the package substrates. Examples disclosed herein include anisotropic conductive films (ACFs) and anisotropic conductive liquid films (ACLFs) that are conductive in one direction and insulative (e.g., not conductive, etc.) in other directions. In some such examples disclosed herein, ACFs and/or ACLFs are disposed between the interconnect bridges and the package substrates, which are conductive vertically therebetween (e.g., in a directional generally perpendicular to the facing surfaces of the interconnect bridges and the package substrates) and not conductive between planarly adjacent contacts on the facing surface of the package substrates and/or the corresponding contact pads on the facing surface of the interconnect bridges. In some examples disclosed herein, passivation layers, such as Silicon Nitrogen (SiN) passivation layers, can be disposed within the cavity of the package substrate and/or on the interconnect bridge to reduce the likelihood of shorts between adjacent pads and/or contacts. In some examples disclosed herein, the anisotropic conductive layers can include conductive metal particles suspended in a nonconductive medium. In other examples disclosed herein, the anisotropic conductive layers can include multilayer particles that are conductive when subject to compressive force. Examples disclosed herein reduce the likelihood of connection faults, such as voids, tin wicking, and/or misalignments, and enable tighter connection tolerances between contacts of the interconnect bridge and contacts of the package substrate.

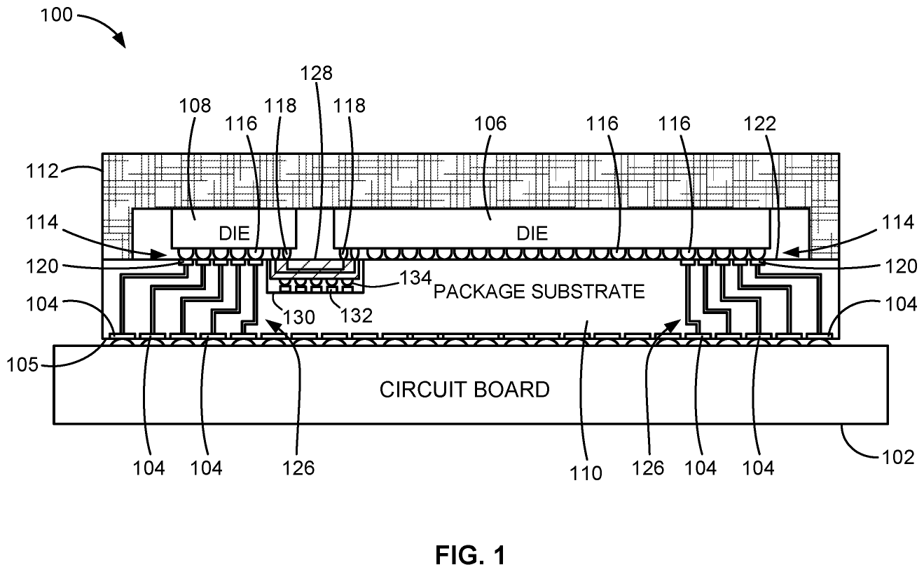

FIG. 1 illustrates an example IC package 100 (e.g., a semiconductor package) constructed in accordance with teachings disclosed herein. In the illustrated example, the IC package 100 is electrically coupled to a circuit board 102 via an array of contact pads 104 (also referred to as “lands”) on a mounting surface 105 (e.g., a bottom surface) of the package. In some examples, the IC package 100 may include balls, pins, and/or pads, in addition to or instead of the contact pads 104, to enable the electrical coupling of the IC package 100 to the circuit board 102. In this example, the IC package 100 includes an example first die 106 and an example second die 108 (sometimes also referred to as chips or chiplets). The dies 106, 108 are two semiconductor (e.g., silicon) dies that are mounted to a package substrate 110 and enclosed by a package lid or mold compound 112. While the example IC package 100 of FIG. 1 includes two dies 106, 108, in other examples, the IC package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

In the illustrated example, each of the dies 106, 108 is electrically and mechanically coupled to the package substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108, and the package substrate 110 (e.g., the interconnects 114) are sometimes referred to as first level interconnects. By contrast, the electrical connections between the IC package 100 and the circuit board 102 (e.g., the contact pads 104, etc.) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps, namely, core bumps 116 and bridge bumps 118. As used herein, core bumps are bumps on dies through which electrical signals pass between the dies and other components either within an IC package containing the dies (e.g., a different die) or external to the IC package. Thus, as shown in the illustrated example, when the dies 106, 108 are mounted to the package substrate 110, the core bumps 116 are physically connected and electrically coupled to contact pads 120 on an inner surface 122 of the package substrate 110. The contact pads 120 on the inner surface 122 of the package substrate 110 are electrically coupled to the contact pads 104 on bottom (mounting) surface 105 of the package substrate 110 (e.g., a surface opposite the inner surface 122) via first internal interconnects 126 within the package substrate 110. As a result, there is a complete signal path between the core bumps 116 of the dies 106, 108 and the contact pads 104 mounted to the circuit board 102 that pass through the contact pads 120 and the first internal interconnects 126 provided therebetween. In the illustrated example of FIG. 1, the first die 106 and the second die 108 are coupled via an example interconnect bridge 128 (e.g., a multi-die interconnect bridge (EMIB), etc.).

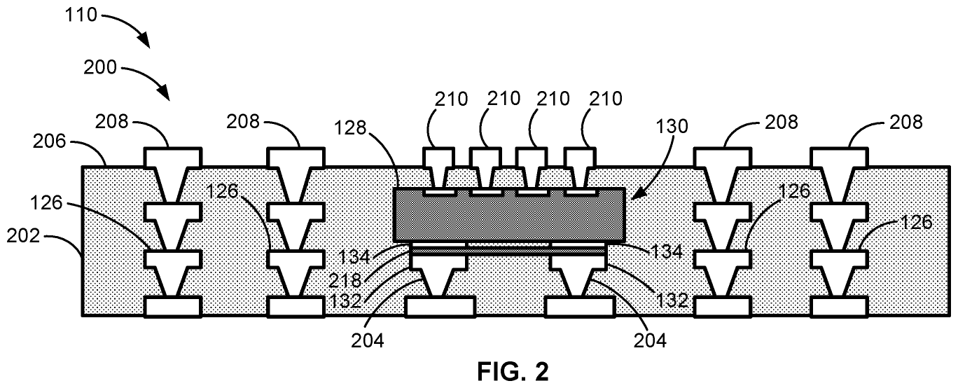

As used herein, bridge bumps are bumps on the dies through which electrical signals pass between different ones of the dies within an IC package. More particularly, bridge bumps differ from core bumps in that bridge bumps electrically connect two or more different dies via an interconnect bridge (e.g., the interconnect bridge 128, etc.)) embedded in an underlying substrate (e.g., the package substrate 110). As represented in FIG. 1, core bumps 116 are typically larger than bridge bumps 118. In some examples, the interconnect bridge 128 and the associated bridge bumps 118 are omitted. In this example, the interconnect bridge 128 is positioned within an example cavity 130 in the inner surface 122 of the package substrate 110. Further, the example interconnect bridge 128 is electrically and mechanically coupled to one or more through silicon vias and/or internal interconnects in the package substrate 110 (e.g., similar to the internal interconnects 126) via the coupling of example first contact pads 132 positioned in the cavity 130 and example second contact pads 134 disposed on the interconnect bridge 128. Therefore, the dies 106, 108 may be electrically coupled to one another and to the package substrate 110 via the bridge bumps 118, the interconnect bridge 128, and the contact pads 132, 134. An example package substrate depicting the electrical coupling of an interconnect bridge and a package substrate is described below in conjunction with FIG. 2.

FIG. 2 is a cross-sectional schematic view of an example portion 200 of the package substrate 110 of FIG. 1 including the interconnect bridge 128 implemented in accordance with teachings of this disclosure. It should be appreciated that the portion 200 and the component disposed therein are not to scale and can have other proportions, shapes, quantities, and/or relative sizes. In some examples, the portion 200 can include additional components and/or layers (not illustrated).

In the illustrated example of FIG. 2, the interconnect bridge 128 is an interconnect bridge disposed within the cavity 130 of FIG. 1. In the illustrated example of FIG. 2, the cavity 130 is formed within an example buildup layer 202. In the illustrated example of FIG. 2, the buildup layer 202 has been filled in around the cavity 130. The buildup layer 202 is an insulative layer of the package substrate that can be used to support and/or house other components of the package substrate 110. In some examples, the buildup layer 202 can be composed of any suitable nonconductive (e.g., dielectric) material, such as glass, resin, or Ajinomoto buildup film (ABF). In some examples, the cavity 130 (and the associated interconnect bridge 128) extend through multiple layers of dielectric material within the buildup layer 202.

In the illustrated example of FIG. 2, the portion 200 of the package substrate 110 includes the first internal interconnects 126 of FIG. 1 and example second internal interconnects 204. In the illustrated example of FIG. 2, the first internal interconnects 126 and the second internal interconnects 204 are vias that enable signal and/or power transmission through the package substrate 110 to components (e.g., dies, etc.) disposed thereon and the interconnect bridge 128, respectively. In other examples, the first internal interconnects 126 and/or the second internal interconnects 204 can have any other suitable arrangement (e.g., routing along various traces in different metal layers connected by conductive vias extending therebetween, etc.). In some examples, a first level interconnect (FLI) layer can be disposed on an example top surface 206 of the portion 200. In the illustrated example of FIG. 2, the top surface 206 includes example first contact pads 208 and example second contact pads 210. In the illustrated example of FIG. 1, the first contact pads 208 are electrically coupled to (e.g., integral with, coupled to, etc.) the first internal interconnects 126 and the second contact pads 210 are electrically coupled to (e.g., integral with, coupled to, etc.) the interconnect bridge 128. In some examples, the first contact pads 208 and the second contact pads 210 can be coupled to the core bumps 116 and bridge bumps 118, respectively, to form the first level interconnects of FIG. 1.

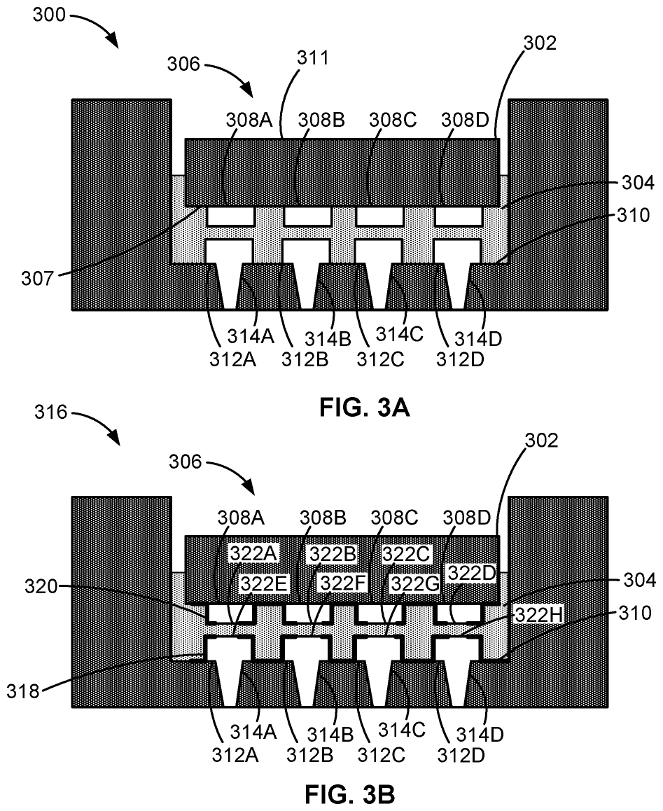

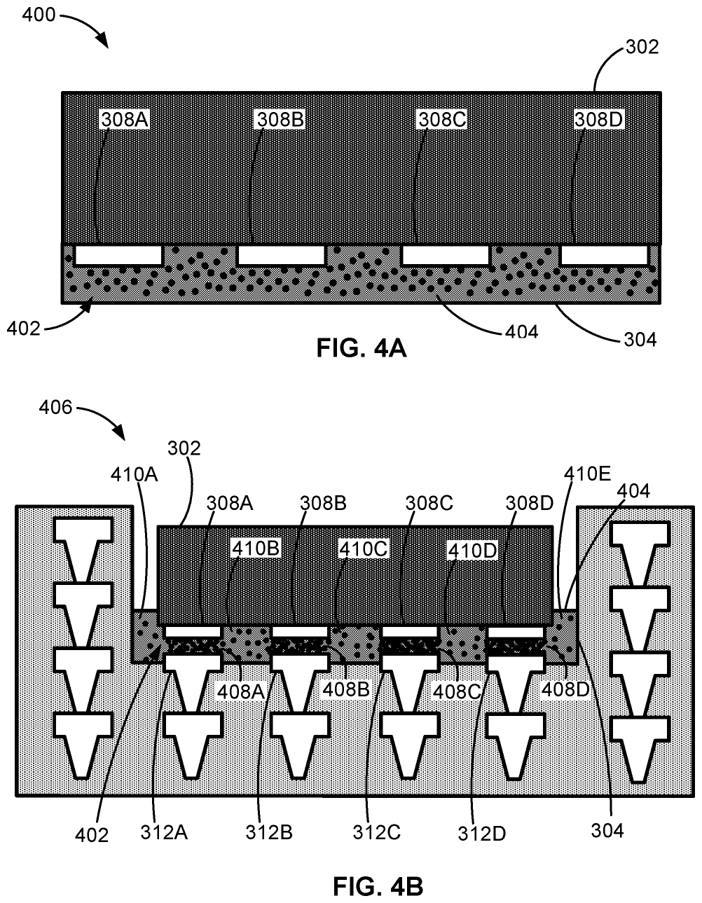

In illustrated example of FIG. 2, the second internal interconnects 204 are electrically coupled (e.g., integral with, coupled to, etc.) to the interconnect bridge 128 via the first contact pads 132 of FIG. 1, the second contact pads 134 of FIG. 1, and an example anisotropic layer 218. In the illustrated example of FIG. 2, the first contact pads 132, the second contact pads 134, and the anisotropic layer 218 are disposed within the cavity 130. The second internal interconnects 204, the first contact pads 132, the second contact pads 134, and the anisotropic layer 218 provide an electrical connection between the interconnect bridge 128 and the bottom of the package substrate 110. In the illustrated example of FIG. 2, the anisotropic layer 218 is disposed between the first contact pads 132 and the second contact pads 134. The anisotropic layer 218 is a selectively conductive material that is comparatively more conductive between vertically adjacent ones (e.g., interfacing pairs) of the first contact pads 132 and the second contact pads 134 and is comparatively less conductive between horizontally and laterally adjacent ones of the first contact pads 132 and horizontally and laterally adjacent ones of the second contact pads 134. That is, the anisotropic layer 218 has a greater conductivity between the vertically adjacent ones of the first contact pads 132 and the second contact pads 134 than between horizontally and laterally adjacent ones of the first contact pads 132 and horizontally and laterally adjacent ones of the second contact pads 134. In some examples, the anisotropic layer 218 can be composed of conductive particles suspended in an insulative substrate. In some examples, the anisotropic layer 218 can be implemented by an ACF and/or ACLF. Example implementations of the anisotropic layer 218 are described below in conjunction with FIGS. 3A-5B.

FIG. 3A is a cross-section view of an example assembly 300 including an example interconnect bridge 302 and an example anisotropic conductive layer 304 implemented in accordance with teachings of this disclosure. In the illustrated example of FIG. 3A, the first assembly 300 is disposed within an example cavity 306 of the package substrate 110. In the illustrated example of FIG. 3A, an example bottom surface 307 (e.g., mounting surface, package-interfacing surface) of the interconnect bridge 302 includes an example first bridge pad 308A, an example second bridge pad 308B, an example third bridge pad 308C, and an example fourth bridge pad 308D. In the illustrated example of FIG. 3A, an example bottom surface 310 of the cavity 306 includes an example first cavity pad 312A, an example second cavity pad 312B, an example third cavity pad 312C, and an example fourth cavity pad 312D. In this examples, the bridge pads 308A, 308B, 308C, 308D protrude from the bottom surface 307 of the interconnect bridge 302 and the cavity pads 312A, 312B, 312C, 312D protrude from the bottom surface 310 of the cavity 306. However, in other examples, at least some of the bridge pads 308A, 308B, 308C, 308D and/or some of the cavity pads 312A, 312B, 312C, 312D are flush with and/or recessed relative to the respective surfaces 307, 310. In some examples, the interconnect bridge 302 can include additional pads (not illustrated) disposed on an example top surface 311 opposite the bottom surface 307 (e.g., the interconnect bridge 302 can include die side pads, similar to the interconnect bridge 128 of FIGS. 1 and 2, etc.).

In the illustrated example of FIG. 3A, the cavity pads 312A, 312B, 312C, 312D are electrically coupled to (e.g., integral with, abutting, coupled to, etc.) an example first via 314A, an example second via 314B, an example third via 314C, and an example fourth via 314D. In some examples, the interconnect bridge 302 is similar to the interconnect bridge 128 of FIGS. 1 and 2, the anisotropic conductive layer 304 is similar to the anisotropic layer 218 of FIG. 2, the cavity 306 is similar to the cavity 130 of FIGS. 1 and 2, the bridge pads 308A, 308B, 308C, 308D are similar to the second contact pads 134 of FIGS. 1 and 2, the cavity pads 312A, 312B, 312C, 312D are similar to the first contact pads 132 of FIGS. 1 and 2, and the vias 314A, 314B, 314C, 314D are similar to the second internal interconnects 204 of FIGS. 1 and 2. In the illustrated example of FIG. 3A, the first assembly 300 includes four bridge pads (e.g., the bridge pads 308A, 308B, 308C, 308D, etc.) and four aligned cavity pads (e.g., the cavity pads 312A, 312B, 312C, 312D, etc.). In other examples, the first assembly 300 can include a different quantity of bridge pads and/or a different quantity of cavity pads 312A, 312B, 312C, 312D. Additionally or alternatively, some or all of the bridge pads can be aligned with multiple ones of the contact pads (e.g., if the bridge pads are larger than the contact pads, etc.). Similarly, in some examples, some or all of the contact pads can be aligned with multiple ones of the bridge pads (e.g., if the contact pads are larger than the bridge pads, etc.).

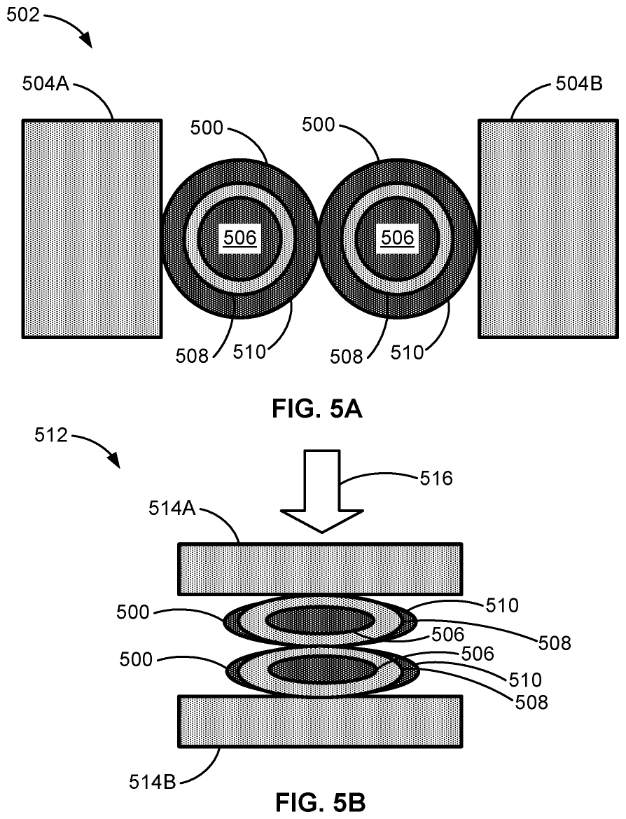

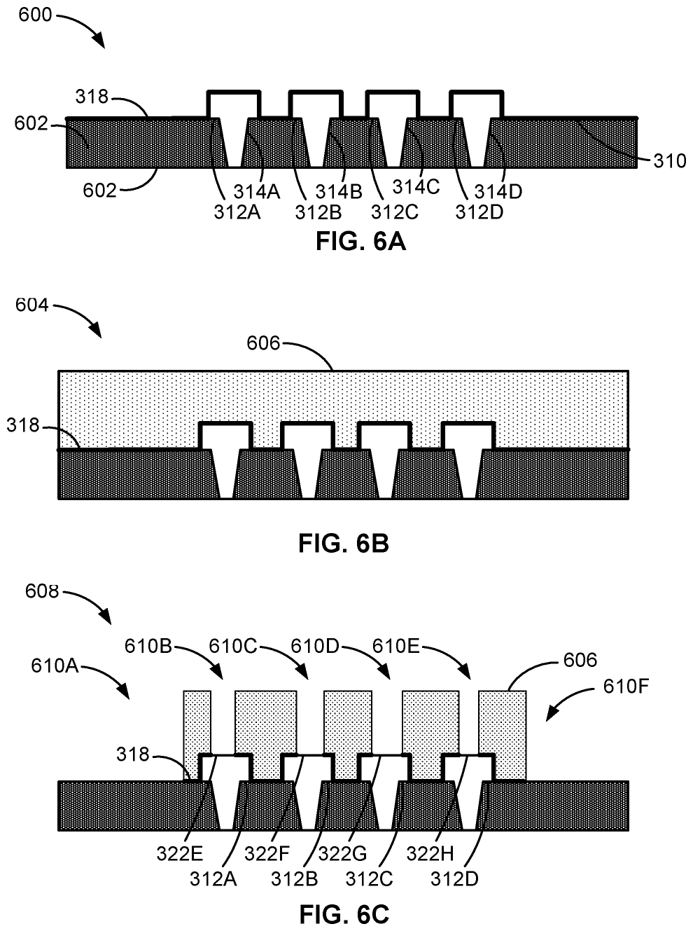

The anisotropic conductive layer 304 is an ACF disposed between the bridge pads 308A, 308B, 308C, 308D and the cavity pads 312A, 312B, 312C, 312D. In other examples, the anisotropic conductive layer 304 can be implemented by an ACLF. In the illustrated example of FIG. 3A, the anisotropic conductive layer 304 is composed of a nonconductive adhesive polymer matrix with conductive particles disposed therein. During the manufacturing of the first assembly 300, the anisotropic conductive layer 304 can be treated (e.g., thermally cured, compressed, electrically charged, etc.) to increase the density of conductive particles between aligned ones (e.g., interfacing pairs) of the bridge pads 308A, 308B, 308C, 308D and the cavity pads 312A, 312B, 312C, 312D (e.g., the first bridge pad 308A and the first cavity pad 312A, the second bridge pad 308B and the second cavity pad 312B, the third bridge pad 308C and the third cavity pad 312C, the fourth bridge pad 308D and the fourth cavity pad 312D, etc.) and to decrease the density of conductive particles in other regions of the anisotropic conductive layer 304. The example sorting (e.g., adjustment to the density) of the conductive particles of the anisotropic conductive layer 304 is described below in conjunction with FIGS. 4A and 4B.

During operation, the dies coupled to the interconnect bridge 302 execute computations and/or other compute functions (e.g., the dies 106, 108 of FIG. 1, etc.). The dies coupled to the interconnect bridge 302 draw power and/or receive signals from the circuit board (e.g., the circuit board 102 of FIG. 1, etc.). In the illustrated example of FIG. 3A, the vias 314A, 314B, 314C, 314D extend through the package substrate 110. In some examples, the vias 314A, 314B, 314C, 314D can interface with the second level interconnects between the package substrate 110 and the circuit board coupled thereto. In some examples, power and/or signals pass through the vias 314A, 314B, 314C, 314D into the cavity pads 312A, 312B, 312C, 312D. After reaching the cavity pads 312A, 312B, 312C, 312D, the power and/or signals are transmitted through the anisotropic conductive layer 304. Because the anisotropic conductive layer 304 is comparatively more conductive vertically (e.g., in a direction extending between ones of the bridge pads 308A, 308B, 308C, 308D and aligned (e.g., interfacing) ones of the cavity pads 312A, 312B, 312C, 312D) and comparatively less conductive in other directions (e.g., laterally, horizontally, etc.), the power and/or signals to and/or from the cavity pads 312A, 312B, 312C, 312D is received from and/or transmitted to the corresponding vertically aligned ones of the bridge pads 308A, 308B, 308C, 308D (e.g., transmissions between the first cavity pad 312A and the first bridge pad 308A, transmissions between the second cavity pad 312B and the second bridge pad 308B, transmissions between the cavity pad 312C and the third bridge pad 308C, and transmissions between the fourth cavity pad 312D and the fourth bridge pad 308D, etc.). That is, the selective conductivity of the anisotropic conductive layer 304 prevents unwanted transmission of power and/or signals (e.g., shorts, etc.) between horizontally and/or laterally adjacent ones of the cavity pads 312A, 312B, 312C, 312D, between horizontally and/or laterally adjacent ones of the bridge pads 308A, 308B, 308C, 308D, and non-vertically aligned ones of the cavity pads 312A, 312B, 312C, 312D and the bridge pads 308A, 308B, 308C, 308D. It should be appreciated that the interconnect bridge 302 can similarly transmit signals through the vias 314A, 314B, 314C, 314D via the bridge pads 308A, 308B, 308C, 308D and the cavity pads 312A, 312B, 312C, 312D and the anisotropic conductive layer 304.

FIG. 3B is a cross-section view of another example second assembly 316 implemented in accordance with teachings of this disclosure. In the illustrated example of FIG. 3B, the second assembly 316 includes the example interconnect bridge 302 of FIG. 3A, the example anisotropic conductive layer 304 of FIG. 3A, the example cavity 306 of FIG. 3A, the example bridge pads 308A, 308B, 308C, 308D of FIG. 3A, the example bottom surface 310 of FIG. 3A, the example cavity pads 312A, 312B, 312C, 312D of FIG. 3A, and the example vias 314A, 314B, 314C, 314D of FIG. 3A. The example second assembly 316 of FIG. 3B is similar to the first assembly 300 of FIG. 3A, except that the second assembly 316 includes an example first passivation layer 318 and an example second passivation layer 320. In the illustrated example of FIG. 3B, the first passivation layer 318 is disposed between the cavity pads 312A, 312B, 312C, 312D and the anisotropic conductive layer 304. In the illustrated example of FIG. 3B, the second passivation layer 320 is disposed between the bridge pads 308A, 308B, 308C, 308D and the anisotropic conductive layer 304. In the illustrated example of FIG. 3B, the first passivation layer 318 is absent and/or thinner on an example first exposed surface 322A of the first bridge pad 308A, an example second exposed surface 322B of the second bridge pad 308B, an example third exposed surface 322C of the third bridge pad 308C, and an example fourth exposed surface 322D of the fourth bridge pad 308D. In the illustrated example of FIG. 3B, the second passivation layer 320 is absent and/or thinner on an example fifth exposed surface 322E of the first cavity pad 312A, an example sixth exposed surface 322F of the second cavity pad 312B, an example seventh exposed surface 322G of the third cavity pad 312C, and an example eighth exposed surface 322H of the fourth cavity pad 312D. In some examples, the passivation layers 318, 320 are absent and/or thinner on less than all of the corresponding exposed surfaces 322A-H as shown in FIG. 3B. In other examples, the passivation layers 318, 320 can be absent and/or thinner across the entire extent of the exposed surface 322A-H.

The passivation layers 318, 320 are electrically insulative layers (e.g., insulative (e.g., dielectric) films, etc.) that reduce the conductivity between non-aligned (e.g., laterally adjacent) ones of the bridge pads 308A, 308B, 308C, 308D, and/or the cavity pads 312A, 312B, 312C, 312D. Because the passivation layers 318, 320 are not disposed on the exposed surfaces 322A, 322B, 322C, 322D, 322E, 322F, 322G, 322H, the passivation layers 318, 320 do not inhibit the transmission of electrical signals and/or power transmitted therethrough. In the illustrated example of FIG. 3B, the exposed surfaces 322A, 322B, 322C, 322D are the bottom surfaces of the bridge pads 308A, 308B, 308C, 308D and are the closest surfaces of the bridge pads 308A, 308B, 308C, 308D to the aligned ones of the cavity pads 312A, 312B, 312C, 312D. Similarly, the exposed surfaces 322E, 322F, 322G, 322H are the top surfaces of the cavity pads 312A, 312B, 312C, 312D and are the closest surfaces of the cavity pads 312A, 312B, 312C, 312D to the aligned ones of the bridge pads 308A, 308B, 308C, 308D. The positioning of the exposed surfaces 322A, 322B, 322C, 322D, 322E, 322F, 322G, 322H reduce (e.g., prevent, etc.) the transmission of signals and/or power between non-aligned ones of the exposed surfaces 322A, 322B, 322C, 322D, 322E, 322F, 322G, 322H. That is, because the passivation layers 318, 320 are nonconductive, the passivation layers 318, 320 reduce (e.g., eliminate, etc.) unwanted transmission between non-vertically aligned ones of the bridge pads 308A, 308B, 308C, 308D, and/or the cavity pads 312A, 312B, 312C, 312D. As such, the passivation layers 318, 320 in conjunction the anisotropic conductive layer 304 reduce the likelihood and/or frequency of unwanted transmission between non-vertically aligned ones of the bridge pads 308A, 308B, 308C, 308D and the cavity pads 312A, 312B, 312C, 312D. The presence of the passivation layers 318, 320 enables the second assembly 316 to have smaller pitches of the bridge pads 308A, 308B, 308C, 308D and/or the cavity pads 312A, 312B, 312C, 312D and/or reduce lateral and/or horizontal spacing therebetween.

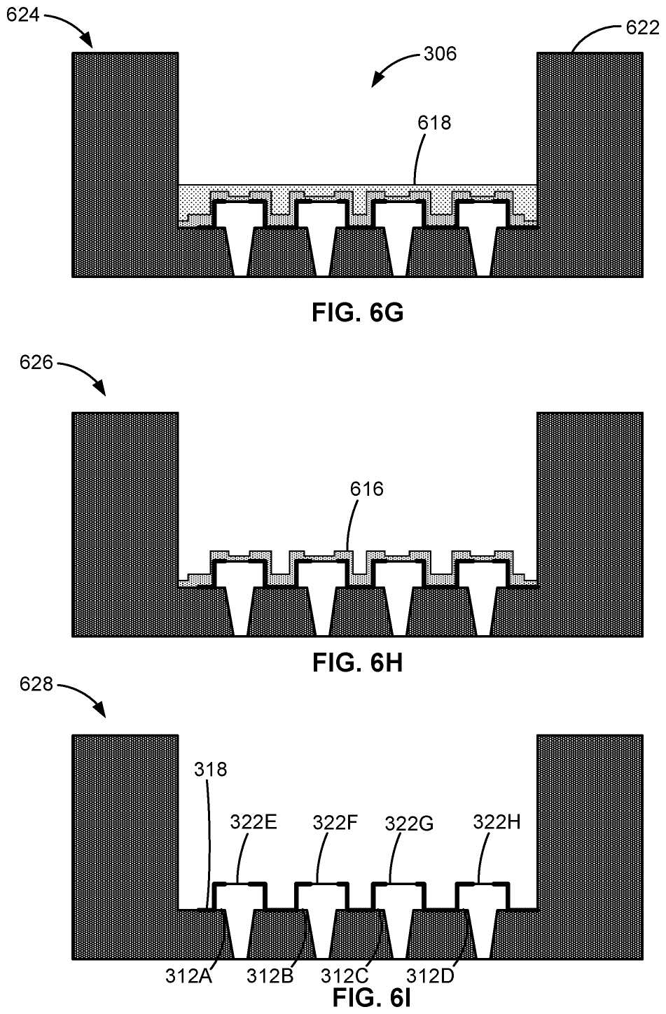

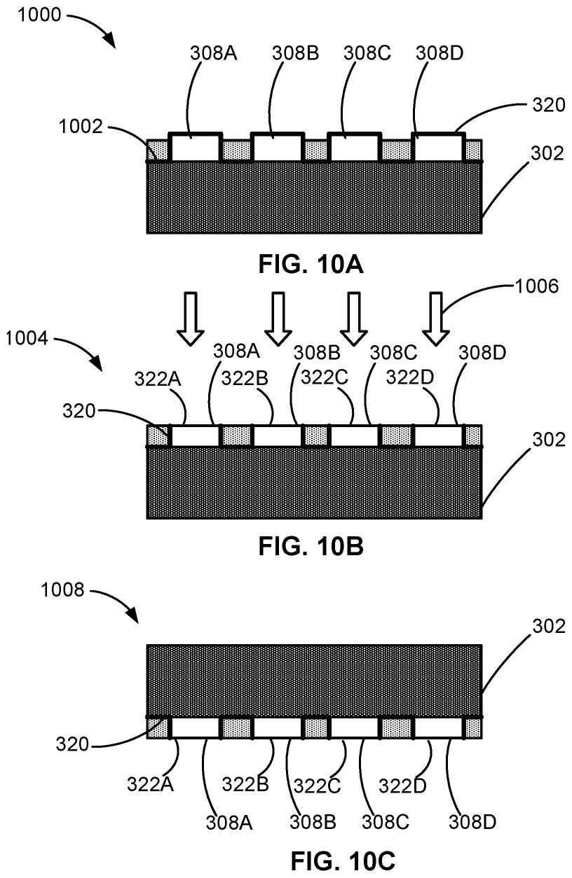

In some examples, the passivation layers 318, 320 are composed of a silicon nitride (SiN) film (e.g., the passivation layers 318, 320 are SiN passivation layers, etc.). In other examples, the passivation layers 318, 320 can be composed of any other suitable insulative material (e.g., aluminum oxide, silicon dioxide, aluminum nitride, etc.). In some examples, one or both of the passivation layers 318, 320 can be absent. Example intermediate steps and operations for manufacturing the first assembly 300 and the second assembly 316 are described below in conjunction with FIGS. 6A-6L and FIG. 11, respectively.

FIG. 4A is a cross-section schematic view of the interconnect bridge 302 of FIGS. 3A and 3B in an example first state 400 before the sorting (e.g., arrangement, distribution) of conductive particles in the anisotropic conductive layer 304. In the illustrated example of FIG. 4A, the anisotropic conductive layer 304 includes example conductive particles 402 disposed in an example substrate 404. In the illustrated example of FIG. 4A, because the conductive particles 402 have not been sorted (e.g., concentrated around the bridge pads 308A, 308B, 308C, 308D, etc.) and/or disposed within a cavity of a substrate package, the conductive particles 402 are evenly distributed in the substrate 404.

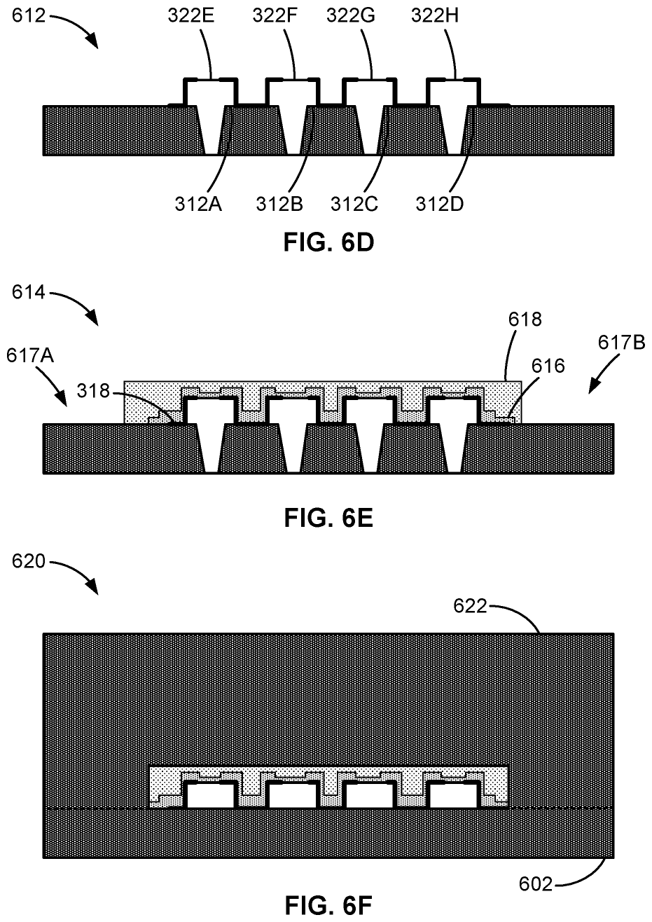

The conductive particles 402 are a plurality of electrically conductive particles. In some examples, the conductive particles 402 can be composed of conductive nanocrystals, a metal powder and/or metal dust. For example, the conductive particles 402 can be composed of silver particles, gold particles, nickel particles, silver-nickel alloy particles, and/or a combination thereof. In other examples, the conductive particles 402 can include any other suitable conductive particles (e.g., copper particles, aluminum particles, graphite particles, etc.). In some examples, the conductive particles 402 can include multiple layers of conductive and nonconductive material. Example conductive particles including nonconductive material is described below in conjunction with FIGS. 5A and 5B. The substrate 404 is a nonconductive (e.g. insulative, dielectric, etc.) substrate that suspends the conductive particles 402. In some examples, the substrate 404 can be implemented by a nonconductive adhesive polymer matrix (e.g., polystyrene, etc.). In other examples, the substrate 404 can be implemented by any other suitable material.

The conductivity of the anisotropic conductive layer 304 is dependent on the distribution of the conductive particles 402 within the substrate 404. For example, if there is a comparatively high concentration of conductive particles 402 in the substrate 404 along a path between a first location (e.g., one of the bridge pads 308A, 308B, 308C, 308D, etc.) and a second location (e.g., an aligned one of the cavity pads 312A, 312B, 312C, 312D, etc.), the anisotropic conductive layer 304 is comparatively more conductive between the first location and the second location. If there is a comparatively low concentration of the conductive particles 402 in the anisotropic conductive layer 304 in the substrate 404 between a third location (e.g., a bridge pad, etc.) and a fourth location (e.g., an adjacent bridge pad, etc.) the anisotropic conductive layer 304 is comparatively less conductive between the third location and the fourth location. In the illustrated example of FIG. 4A, the conductive particles 402 are evenly distributed within the substrate 404 (e.g., there are no portions of the substrate 404 with a high concentration or low concentration of conductive particles 402, etc.). As such, the anisotropic conductive layer 304 is not selectively conductive in the first state 400.

FIG. 4B is a cross-section schematic detail view of the interconnect bridge 302 of FIGS. 3A and 3B in an example second state 406 after the sorting of the anisotropic conductive layer 304. In the illustrated example of FIG. 4B, the anisotropic conductive layer 304 includes the example conductive particles 402 of FIG. 4A and the example substrate 404 of FIG. 4A. In the illustrated example of FIG. 4B, the interconnect bridge 302 has been disposed on the bottom surface 310 of FIG. 3A of the cavity 306 of FIG. 3A. In the illustrated example of FIG. 4B, the anisotropic conductive layer 304 is disposed between the bridge pads 308A, 308B, 308C, 308D of FIGS. 3A and 3B and the cavity pads 312A, 312B, 312C, 312D of FIGS. 3A and 3B. In the illustrated example of FIG. 4B, the conductive particles 402 have been sorted (e.g., arranged, distributed, etc.) within the substrate 404 forming an example first high concentration region 408A, an example second high concentration region 408B, an example third high concentration region 408C, an example fourth high concentration region 408D, an example first low concentration region 410A, an example second low concentration region 410B, an example third low concentration region 410C, an example fourth low concentration region 410C and an example fifth low concentration region 410E.

In the illustrated example of FIG. 4B, the conductive particles 402 of the anisotropic conductive layer 304 has been sorted from the first state 400 of FIG. 4A to the second state 406 (e.g., to form the high concentration regions 408A, 408B, 408C, 408D and low concentration regions 410A, 410B, 410C, 410D, 410E, etc.) via one or more sorting processes. For example, the conductive particles 402 of the anisotropic conductive layer 304 can be sorted via surface tension and/or capillary action between respective ones of the bridge pads 308A, 308B, 308C, 308D and the cavity pads 312A, 312B, 312C, 312D due to the comparatively narrow space between aligned ones (e.g., interfacing pairs) of the bridge pads 308A, 308B, 308C, 308D and the cavity pads 312A, 312B, 312C, 312D. In some examples, thermally curing the anisotropic conductive layer 304 can increase the rate of the sorting of the conductive particles 402 via surface tension and/or capillary action. Additionally or alternatively, if the conductive particles 402 are magnetic, the particles can be sorted into the high concentration regions 408A, 408B, 408C, 408D and low concentration regions 410A, 410B, 410C, 410D, 410E by magnetizing some or all of the bridge pads 308A, 308B, 308C, 308D and/or the cavity pads 312A, 312B, 312C, 312D. In some such examples, the magnetization of the bridge pads 308A, 308B, 308C, 308D and/or the cavity pads 312A, 312B, 312C, 312D attaches and magnetizes ones of the conductive particles 402, which causes the formation of the high concentration regions 408A, 408B, 408C, 408D between the aligned ones of the bridge pads 308A, 308B, 308C, 308D and/or the cavity pads 312A, 312B, 312C, 312D. In some examples, depending on the type of the conductive particles 402, the sorting can be omitted. An example of conductive particles that do not require a sorting process is described below in conjunction with FIGS. 5A and 5B.

As described above in conjunction with FIG. 4A, the conductivity of the anisotropic conductive layer 304 is dependent on the concentration and distribution of the conductive particles 402 within the substrate 404. In the illustrated example of FIG. 4B, the high concentration regions 408A, 408B, 408C, 408D are disposed between vertically aligned ones of the bridge pads 308A, 308B, 308C, 308D and the cavity pads 312A, 312B, 312C, 312D and the low concentration regions 410A, 410B, 410C, 410D, 410E are disposed between vertically aligned pairs of the bridge pads 308A, 308B, 308C, 308D and the cavity pads 312A, 312B, 312C, 312D. As such, the high concentration regions 408A, 408B, 408C, 408D cause the anisotropic conductive layer 304 to be comparatively more conductive between interfacing pairs of the bridge pads 308A, 308B, 308C, 308D and the cavity pads 312A, 312B, 312C, 312D and the low concentration regions 410A, 410B, 410C, 410D, 410E cause the anisotropic conductive layer 304 to be comparatively less conductive laterally and horizontally between the interfacing pairs of the bridge pads 308A, 308B, 308C, 308D and the cavity pads 312A, 312B, 312C, 312D.

FIG. 5A is a schematic view of example multilayer conductive particles 500 in an example first configuration 502. In the illustrated example of FIG. 5A, the multilayer conductive particles 500 are disposed between an example first pad 504A and an example second pad 504B. In the illustrated example of FIG. 5A, each of the multilayer conductive particles 500 has an example core 506, an example first coating 508, and an example second coating 510. In the illustrated example of FIG. 5A, the pads 504A, 504B are laterally adjacent. In some such examples, the pads 504A, 504B can correspond to laterally and/or horizontally adjacent ones of the bridge pads 308A, 308B, 308C, 308D of FIGS. 3A and 3B and/or laterally and/or horizontally adjacent ones of the cavity pads 312A, 312B, 312C, 312D. The conductive particles 500 can implement the conductive particles 402 of the anisotropic conductive layer 304 of FIGS. 4A and 4B.

In the illustrated example of FIG. 5A, each of the conductive particles 500 is composed of the core 506, the first coating 508 surrounding (e.g., coating, encompassing, encasing, etc.) the core 506, and the second coating 510 surrounding (e.g., coating, encompassing, encasing, etc.) the first coating 508. The core 506 and the second coating 510 are composed of one or more nonconductive (e.g., insulative, dielectric, etc.) material(s). For example, the core 506 and the second coating 510 can be composed of a nonconductive polymer (e.g. the core 506 is a polymer core, the second coating 510 is a polymer coating, etc.). In other examples, the core 506 and/or the second coating 510 can be composed of any other suitable nonconductive material (e.g., a glass, a composite, etc.). In some examples, the core 506 and the second coating 510 are composed of different materials. The first coating 508 is composed of a conductive material. For example, the first coating 508 can be composed of a metal (e.g., copper, silver, gold, nickel, silver nickel alloy, etc.). In some such examples, the first coating 508 is a metal coating. In other examples, the first coating 508 can be composed of any other suitable conductive material. In other examples, the conductive particles 500 can be composed of any suitable number of conductive and/or nonconductive layers.

The first configuration 502 of the conductive particles 500 reduces (e.g., eliminates, etc.) the conductivity between the first pad 504A and the second pad 504B. In the illustrated example of FIG. 5A, the second coating 510 blocks contact of the conductive portions of the conductive particles 500 (e.g., the first coating 508, etc.). That is, in the first configuration 502 of FIG. 5A, the low conductivity of the second coating 510 reduces (e.g., eliminates, etc.) the transmission of electric signals and/or power between the first pad 504A and the second pad 504B. Accordingly, the first configuration 502 of the conductive particles 500 reduces (e.g., eliminates, etc.) the transmission of power and electric signals between the first pad 504A and the second pad 504B.

FIG. 5B is a schematic view of the example multilayer conductive particles 500 of FIG. 5A in an example second configuration 512. In the illustrated example of FIG. 5B, the multilayer conductive particles 500 are disposed between an example third pad 514A and an example fourth pad 514B. In the illustrated example of FIG. 5B, the pads 514A, 514B are vertically adjacent. In some such examples, the pads 514A, 514B can correspond to interfacing pairs of the bridge pads 308A, 308B, 308C, 308D and the cavity pads 312A, 312B, 312C, 312D (e.g., the first bridge pad 308A and the first cavity pad 312A, the second bridge pad 308B and the second cavity pad 312B, the third bridge pad 308C and the third cavity pad 312C, and the fourth bridge pad 308D and the fourth cavity pad 312D, etc.). In the illustrated example of FIG. 5B, the conductive particles 500 are subject to an example compressive force 516.

The compressive force 516 is a pressure (e.g., a force applied over an area, etc.) applied to the pads 514A, 514B. In the illustrated example of FIG. 5B, the compressive force 516 causes the conductive particles 500 to distort (e.g., bend, compress, etc.), such that the first coating 508 of adjacent ones of the conductive particles 500 abut (e.g., contact) each other and the pads 514A, 514B. The comparatively high conductivity of the first coating 508 and the abutment thereof enables power and/or electrical signals to be transmitted between the pads 514A, 514B via the conductive particles 500. As such, in the second configuration 512, the conductive particles 500 are able to transmit electrical signals and power. Particularly, the application of pressure (e.g., the compressive force 516, etc.) along an axis (e.g., in a direction, etc.) causes the conductive particles 500 to be conductive in that direction. In assemblies including the conductive particles 500, the application of a compressive force in the vertical direction causes the conductive particles 500 to be conduct power and/or electric signals between the pads 514A, 514B due to the reduced clearance and compression between the pads 514A, 514B. In some such examples, the anisotropic layers including the conductive particles 500 are conductive in the vertical direction and not conductive (e.g., insulative, etc.) in the lateral and horizontal directions when a vertical compressive force is applied. For example, an interconnect bridge (e.g., the interconnect bridge 302 of FIGS. 3A and 3B, etc.) abutting an anisotropic layer including the conductive particles 500 can be preloaded (e.g., disposed within the cavity such that a compressive force/pressure is constantly applied to interconnect bridge 302 and/or the package substrate 110, etc.) within the package substrate 110 in compression. In other examples, the compressive force 516 can be applied in any other suitable manner.

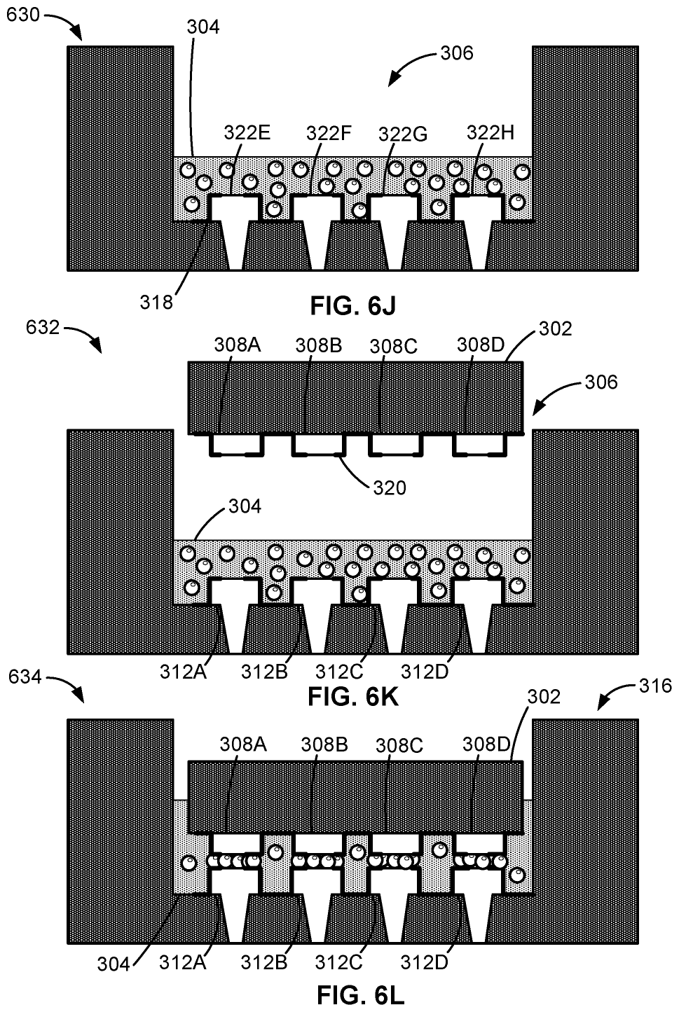

FIGS. 6A-6L depict a plurality of intermediate stages in an example process to manufacture the second assembly 316 of FIG. 3B. In some examples, the first assembly 300 of FIG. 3A can be manufactured via an example process similar to the process associated with the intermediate stages of FIGS. 6A-6L (e.g., by omitting the intermediate stages of FIGS. 6A-6E and 6G, etc.). In other examples, an assembly similar to the first assembly 300 of FIG. 3A and/or the second assembly 316 of FIG. 3B can be manufactured via a process that includes intermediate stages different than the ones illustrated in conjunction with FIGS. 6A-6L. It should be appreciated that other processes can be used to manufacture the first assembly 300 of FIG. 3A and/or the second assembly 316 of FIG. 3B. Example operations to manufacture the first assembly 300 of FIG. 3A and/or the second assembly 316 of FIG. 3B via the intermediate stages of FIGS. 6A-6L are described below in conjunction with FIG. 7.

FIG. 6A is a cross-sectional view of an example first intermediate stage 600 of the fabrication of the second assembly 316 of FIG. 3B. In the illustrated example of FIG. 6A, the first intermediate stage 600 occurs during the fabrication on the package substrate 110 of FIG. 1. In the illustrated example of FIG. 6A, the package substrate 110 includes the cavity pads 312A, 312B, 312C, 312D of FIGS. 3A and 3B, vias 314A, 314B, 314C, 314D of FIGS. 3A and 3B, and an example buildup layer portion 602. In some examples, the example buildup layer portion 602 is a portion of the buildup layer 202 of FIG. 2. In the illustrated example of FIG. 6A, the package substrate 110 has been fabricated such that the vias 314A, 314B, 314C, 314D of FIGS. 3A and 3B extend to the bottom surface 310 of FIGS. 3A and 3B and abut the cavity pads 312A, 312B, 312C, 312D. In the illustration of FIG. 6A, the example first passivation layer 318 has been deposited on the bottom surface 310 and the cavity pads 312A, 312B, 312C, 312D. For example, the first passivation layer 318 can be deposited via a thin film deposition (TFD) technique, etc. Additionally or alternatively, the first passivation layer 318 can be deposited via any other suitable deposition method (e.g., electroplating, atomic layer deposition (ALD), chemical vapor deposition (CVD), physical vapor deposition (PVD), etc.). In the illustrated example of FIG. 6A, the first passivation layer 318 is deposited as a thin film with equal thickness along the bottom surface 310, the tops of the cavity pads 312A, 312B, 312C, 312D, and the sides of the cavity pads 312A, 312B, 312C, 312D.

FIG. 6B is a cross-sectional view of an example second intermediate stage 604 of the fabrication of the second assembly 316 of FIG. 3B. In some examples, the second intermediate stage 604 occurs after the first intermediate stage 600 of FIG. 6A. In the illustrated example of FIG. 6B, an example dry film resist layer 606 has been deposited on the passivation layer 318 during the intermediate stage 600 of FIG. 6A. For example, the example dry film resist layer 606 can be deposited via lamination. In other examples, the dry film resist layer 606 can be deposited via ALD, CVD, etc.

FIG. 6C is a cross-sectional view of an example third intermediate stage 608 of the fabrication of the second assembly 316 of FIG. 3B. In some examples, the third intermediate stage 608 occurs after the second intermediate stage 604 of FIG. 6B. In the illustrated example of FIG. 6C, an example first opening 610A, an example second opening 610B, an example third opening 610C, an example fourth opening 610D, an example fifth opening 610E, and an example sixth opening 610F has been formed in the dry film resist layer 606 of FIG. 6B. In the illustrated example of FIG. 6C, the openings 610A, 610B, 610C, 610D, 610E, 610F have exposed the first passivation layer 318 which has been removed to form the fifth exposed surface 322E of FIG. 3B, the sixth exposed surface 322F of FIG. 3B, the seventh exposed surface 322G of FIG. 3B, and the eighth exposed surface 322H of FIG. 3B on the first cavity pad 312A, the second cavity pad 312B, the third cavity pad 312C, and the fourth cavity pad 312D, respectively. In some examples, the portions of the dry film resist layer 606 corresponding to the openings 610A, 610B, 610C, 610D, 610E, 610F can be removed via lithography techniques. For example, the portions of the dry film resist layer 606 corresponding to the openings 610A, 610B, 610C, 610D, 610E, 610F can be selectively exposed to ultraviolet light (e.g., ultraviolet radiation, etc.) by applying a photomask to the dry film resist, which causes those portions to become soluble. In some such examples, the dry film resist layer 606 can be exposed to an aqueous bath, which removes the portions of the dry film resist layer 606 corresponding to the openings 610A, 610B, 610C, 610D, 610E, 610F. The exposed portions of the first passivation layers 318 (e.g., caused by the removal of the portions of the dry film resist layer 606, etc.) can be removed via etching (e.g., plasma etching, etc.). The remaining portions of the dry film resist layer 606 shield portions of the first passivation layer 318 from the plasma etching.

FIG. 6D is a cross-sectional view of an example fourth intermediate stage 612 of the fabrication of the second assembly 316 of FIG. 3B. In some examples, the fourth intermediate stage 612 occurs after the third intermediate stage 608 of FIG. 6C. In the illustrated example of FIG. 6D, the remaining portions of the dry film resist layer 606 of FIG. 6B has been removed. For example, the dry film resist layer 606 can be removed by applying ultraviolet radiation and applying an aqueous bath to the dry film resist layer 606. In other examples, the remaining portions of the dry film resist layer 606 can be removed via any other suitable process.

FIG. 6E is a cross-sectional view of an example fifth intermediate stage 614 of the fabrication of the second assembly 316 of FIG. 3B. In some examples, the fifth intermediate stage 614 occurs after the fourth intermediate stage 612 of FIG. 6D. In the illustrated example of FIG. 6E, an example seed layer 616 has been deposited on the first passivation layer 318 and the exposed surfaces 322E, 322F, 322G, 322H of the cavity pads 312A, 312B, 312C, 312D. In some examples, an example first opening 617A and an example second opening 617B have been formed in the seed layer 616. In the illustrated example of FIG. 6E, an example electrode layer 618 has been deposited on the seed layer 616 (e.g., not including the portions of the bottom surfaces associated with the openings 617A, 617B, etc.). The electrode layer 618 can be composed of any suitable material, including copper. The seed layer 616 can be deposited via a deposition technique, such as ALD, CVD, PVD, etc. In some examples, the openings 617A, 617B can be formed in the seed layer 616 via lithography (e.g., dry film resist lithography, etc.). In some examples, after the formation of the openings 617A, 617B, the electrode layer 618 can be deposited via electroplating on the seed layer 616. In some examples, the deposition of the seed layer 616 is omitted. In some such examples, the electrode layer 618 can be deposited via any other suitable technique.

FIG. 6F is a cross-sectional view of an example sixth intermediate stage 620 of the fabrication of the second assembly 316 of FIG. 3B. In some examples, the sixth intermediate stage 620 occurs after the fifth intermediate stage 614 of FIG. 6E. In the illustrated example, an example second buildup layer portion 622 is deposited on the electrode layer 618 of FIG. 6E and the first buildup layer portion 602 of FIG. 6A. For example, the second buildup layer portion 622 can be deposited via lamination. In other examples, the second buildup layer portion 622 can be deposited via any other suitable deposition technique. In some examples, the second buildup layer portion 622 includes multiple layers of a dielectric material individually added in succession. In some examples, the second buildup layer portion 622 can be composed of ABF. In other examples, the second buildup layer portion 622 can be composed of any other suitable insulative material. In some examples, the second buildup layer portion 622 and the first build layer portion 602 form the buildup layer 202 of FIG. 2.

FIG. 6G is a cross-sectional view of an example seventh intermediate stage 624 of the fabrication of the second assembly 316 of FIG. 3B. In some examples, the seventh intermediate stage 624 occurs after the sixth intermediate stage 620 of FIG. 6F. In the illustrated example of FIG. 6G, the cavity 306 of FIG. 3B has been formed in the second buildup layer portion 622. For example, the cavity 306 can be formed via drilling. In other examples, the cavity 306 can be formed via any other suitable material removal process. In some examples, the cavity 306 is formed such that the electrode layer 618 is exposed.

FIG. 6H is a cross-sectional view of an example eighth intermediate stage 626 of the fabrication of the second assembly 316 of FIG. 3B. In some examples, the eighth intermediate stage 626 occurs after the seventh intermediate stage 624 of FIG. 6G. In the illustrated example of FIG. 6H, the electrode layer 618 has been removed. For example, the electrode layer 618 can be removed via etching (e.g., wet etching, ion etching, plasma etching, etc.). In other examples, the electrode layer 618 can be removed via any other suitable material removal process. In the illustrated example of FIG. 6H, the removal of the electrode layer 618 exposes the seed layer 616.

FIG. 6I is a cross-sectional view of an example ninth intermediate stage 628 of the fabrication of the second assembly 316 of FIG. 3B. In some examples, the ninth intermediate stage 628 occurs after the eighth intermediate stage 626 of FIG. 6H. In some examples, the eighth intermediate stage 626 occurs after the seventh intermediate stage 624 of FIG. 6G. In the illustrated example of FIG. 6H, the seed layer 616 has been removed. For example, the seed layer 616 can be removed via etching (e.g., wet etching, ion etching, plasma etching, etc.). In other examples, the seed layer 616 can be removed via any other suitable material removal process. In the illustrated example of FIG. 6H, the removal of the seed layer 616 exposes the first passivation layer 318 and the exposed surfaces 322E, 322F, 322G, 322H of the cavity pads 312A, 312B, 312C, 312D, respectively.

FIG. 6J is a cross-sectional view of an example tenth intermediate stage 630 of the fabrication of the second assembly 316 of FIG. 3B. In some examples, the tenth intermediate stage 630 occurs after the ninth intermediate stage 628 of FIG. 6G. In the illustrated example of FIG. 6J, the anisotropic conductive layer 304 has been deposited within the cavity 306 onto the bottom surface 310, the first passivation layer 318, and the exposed surfaces 322E, 322F, 322G, 322H. For example, the anisotropic conductive layer 304 can be deposited as an ACLF via inkjetting. In other examples, the anisotropic conductive layer 304 can be deposited in any other suitable method. It should be appreciated that the conductive particles of the anisotropic conductive layer 304 have not been set (e.g., sorted, subjected to a compressive force, etc.) and, as such, the anisotropic conductive layer 304 is not anisotropically conductive during the intermediate stage 630 of FIG. 6J.

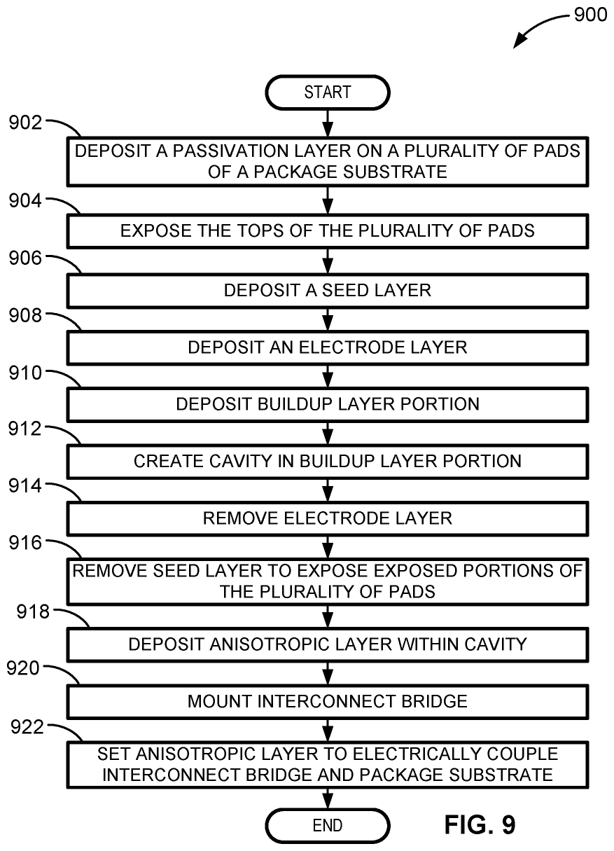

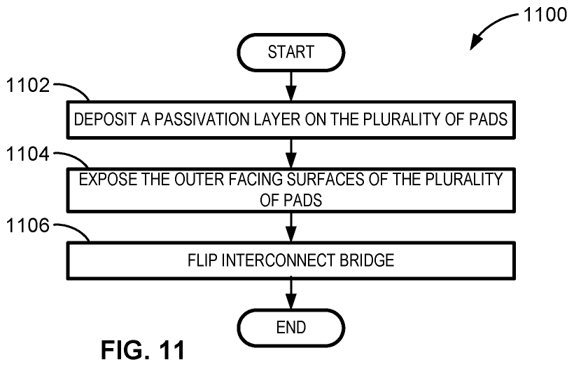

FIG. 6K is a cross-sectional view of an example eleventh intermediate stage 632 of the fabrication of the second assembly 316 of FIG. 3B. In some examples, the eleventh intermediate stage 632 occurs after the tenth intermediate stage 630 of FIG. 6J. In the illustrated example of FIG. 6K, the interconnect bridge 302 of FIGS. 3A and 3B is mounted into the cavity 306. In the illustrated example of FIG. 6K, the interconnect bridge 302 includes the bridge pads 308A, 308B, 308C, 308D and the second passivation layer 320. For example, the interconnect bridge 302 can be mounted as a flip chip. In other examples, the interconnect bridge 302 can be mounted in any other suitable manner. In the illustrated example of FIG. 6K, the interconnect bridge 302 is mounted such the bridge pads 308A, 308B, 308C, 308D are aligned with respective ones of the cavity pads 312A, 312B, 312C, 312D. In some examples, if the anisotropic conductive layer 304 includes the conductive particles 500 of FIGS. 5A and 5B, the interconnect bridge 302 can be mounted in a manner that applies a compressive force to the interconnect bridge 302 (e.g., the compressive force 516 of FIG. 5B, etc.). Example intermediate steps and operations for the manufacturing of the interconnect bridge 302 are described below in conjunction with FIGS. 10A-10C and FIG. 11, respectively. Alternative intermediate steps for the deposition of the anisotropic conductive layer 304 are described below in conjunction with FIG. 12

FIG. 6L is a cross-sectional view of an example twelfth intermediate stage 634 of the fabrication of the second assembly 316 of FIG. 3B. In some examples, the twelfth intermediate stage 634 occurs after the eleventh intermediate stage 632 of FIG. 6K. In the illustrated example of FIG. 6K, the anisotropic conductive layer 304 has been set (e.g., made to be anisotropic, etc.). For example, the anisotropic conductive layer 304 can be thermally cured to cause the anisotropic conductive layer 304 to form high concentration regions (e.g., the high concentration regions 408A, 408B, 408C, 408D of FIG. 4B, etc.) adjacent to the bridge pads 308A, 308B, 308C, 308D and the cavity pads 312A, 312B, 312C, 312D, such that anisotropic conductive layer 304 is able to conduct power and/or electric signals between vertically adjacent ones (e.g., interfacing pairs) of the bridge pads 308A, 308B, 308C, 308D and the cavity pads 312A, 312B, 312C, 312D. In some such examples, the anisotropic conductive layer 304 can be thermally cured via thermal compressive bonding (TCB). Additionally or alternatively, if the conductive particles 402 of the anisotropic conductive layer 304 are magnetic, the anisotropic conductive layer 304 can be set by magnetizing one or more of the bridge pads 308A, 308B, 308C, 308D and/or the cavity pads 312A, 312B, 312C, 312D. In some examples, if the anisotropic conductive layer 304 includes the conductive particles 500, the anisotropic conductive layer 304 can be set by applying a compressive force to the interconnect bridge 302 (e.g., the compressive force 516 of FIG. 5B, etc.). In some such examples, the conductive particles 500 do not sort into regions of differing densities within the anisotropic conductive layer 304.

FIG. 7 is a flowchart representative of an example operations for manufacturing the first assembly 300 of FIG. 3A and the second assembly of FIG. 3B. The example operations 700 begin at block 702, at which the first passivation layer 318 is deposited on a plurality of pads (e.g., the cavity pads 312A, 312B, 312C, 312D, etc.) of a package substrate. For example, the first passivation layer 318 can be deposited via a thin film deposition (TFD), electroplating, atomic layer deposition (ALD), chemical vapor deposition (CVD), physical vapor deposition (PVD), and/or a combination thereof. In some examples, if the first assembly 300 is being manufactured, the execution of block 702 can be omitted. The point of fabrication after completion of block 702 corresponds to the structure of the first intermediate stage 600 of FIG. 6A.

At block 704, the dry film resist layer 606 is deposited on the passivation layer 318. For example, the example dry film resist layer 606 can be deposited via lamination. In some examples, if the first assembly 300 is being manufactured, the execution of block 704 can be omitted. The point of fabrication after completion of block 704 corresponds to the structure of the first intermediate stage 604 of FIG. 6B. At block 706, a photoresist pattern is applied to the dry film resist layer 606. For example, the photoresist pattern can be applied by selectively exposing a portion of the dry film resist layer 606 to ultraviolet light. In some such examples, the exposure of portions of the dry film resist layer 606 causes those portions to be soluble. In some examples, if the first assembly 300 is being manufactured, the execution of block 706 can be omitted.

At block 708, the exposed portions of the dry film resist layer 606 are removed. For example, the dry film resist layer 606 can be subjected to (e.g., exposed to, etc.) a bath to dissolve the exposed portions of the dry film resist layer 606. In some examples, if the first assembly 300 is being manufactured, the execution of block 708 can be omitted. At block 710, the exposed portions of the first passivation layer 318 are removed. For example, the portions of the first passivation layer 318 exposed during the execution of blocks 704 and 706 are removed. In some examples, the exposed portions of the first passivation layer 318 can be removed via etching (e.g., plasma etching, wet etching, reactive ion etching, etc.) and/or any other suitable material removal technique (e.g., ion milling, etc.). In some examples, if the first assembly 300 is being manufactured, the execution of block 710 can be omitted. The point of fabrication after completion of block 708 corresponds to the structure of the third intermediate stage 608 of FIG. 6C.

At block 712, the remaining portions of the dry film resist layer 606 are removed. For example, the dry film resist layer 606 can be removed by applying ultraviolet radiation and applying an aqueous bath to the dry film resist layer 606. In other examples, the remaining portions of the dry film resist layer 606 can be removed via any other suitable process. In some examples, if the first assembly 300 is being manufactured, the execution of block 712 can be omitted. The point of fabrication after completion of block 708 corresponds to the structure of the fourth intermediate stage 612 of FIG. 6D.

At block 714, the seed layer 616 is deposited on the first passivation layer 318 and the exposed portions. For example, the seed layer 616 can be deposited via ALD, CVD, PVD, etc. In some examples, portions of the seed layer 616 can be removed (e.g., corresponding to the openings 617A, 617B of FIG. 6E, etc.). In some such examples, the removed portions can be removed via lithography. At block 716, the electrode layer 618 is deposited on the seed layer 616. In some examples, the electrode layer 618 can be electroplated on the seed layer 616. In other examples, the electrode layer 618 can be deposited via any other suitable deposition method. The point of fabrication after completion of block 714 corresponds to the structure of the fifth intermediate stage 614 of FIG. 6E.

At block 718, the second buildup layer portion 622 is deposited. For example, the second buildup layer portion 622 can be deposited on the electrode layer 618 of FIG. 6E and the first buildup layer portion 602 of FIG. 6A. For example, the second buildup layer portion 622 can be deposited via lamination. The point of fabrication after completion of block 716 corresponds to the structure of the sixth intermediate stage 620 of FIG. 6F. At block 720, the cavity 306 is created in the second buildup layer 622. For example, the cavity 306 can be created via drilling. In other examples, the cavity 306 can be created via any other suitable material removal process. The point of fabrication after completion of block 720 corresponds to the structure of the seventh intermediate stage 624 of FIG. 6G.

At block 722, the electrode layer 618 is removed. For example, the electrode layer 618 can be removed via etching (e.g., wet etching, ion etching, plasma etching, etc.). In other examples, the electrode layer 618 can be removed via any other suitable material removal process. The point of fabrication after completion of block 720 corresponds to the structure of the eighth intermediate stage 626 of FIG. 6G. At block 724, the seed layer 616 is removed to expose the exposed surfaces 322E, 322F, 322G, 322H of the cavity pads 312A, 312B, 312C, 312D. For example, the seed layer 616 can be removed via etching (e.g., wet etching, ion etching, plasma etching, etc.). In other examples, the seed layer 616 can be removed via any other suitable material removal process. The point of fabrication after completion of block 722 corresponds to the structure of the ninth intermediate stage 628 of FIG. 6H.

At block 726, the anisotropic conductive layer 304 is deposited within the cavity 306. For example, the anisotropic conductive layer 304 can be deposited onto the bottom surface 310, the first passivation layer 318, and the exposed surfaces 322E, 322F, 322G, 322H. For example, the anisotropic conductive layer 304 can be deposited as an ACLF via inkjetting. In other examples, the anisotropic conductive layer 304 can be deposited in any other suitable method. The point of fabrication after completion of block 724 corresponds to the structure of the tenth intermediate stage 630 of FIG. 6J.

At block 728, the interconnect bridge 302 of FIGS. 3A and 3B is mounted into the cavity 306. For example, the interconnect bridge 302 can be mounted as a flip chip. In other examples, the interconnect bridge 302 can be mounted in any other suitable manner. In some examples, if the anisotropic conductive layer 304 includes the conductive particles 500 of FIGS. 5A and 5B, the interconnect bridge 302 can be mounted in a manner that applies a compressive force (e.g., the compressive force 516 of FIG. 5B, etc.) to the interconnect bridge 302 with a. The point of fabrication after completion of block 726 corresponds to the structure of the eleventh intermediate stage 632 of FIG. 6K.

At block 730, the anisotropic conductive layer 304 is set. For example, the anisotropic conductive layer 304 can be thermally cured to cause the anisotropic conductive layer 304 to form high concentration regions (e.g., the high concentration regions 408A, 408B, 408C, 408D of FIG. 4B, etc.) adjacent to the bridge pads 308A, 308B, 308C, 308D and the cavity pads 312A, 312B, 312C, 312D, such that anisotropic conductive layer 304 is able to conduct power and/or electric signals between adjacent ones of the bridge pads 308A, 308B, 308C, 308D and/or the cavity pads 312A, 312B, 312C, 312D. In some such examples, the anisotropic conductive layer 304 can be thermally cured via thermal compressive bonding (TCB). Additionally or alternatively, if the conductive particles 402 of the anisotropic conductive layer 304 are magnetic, the anisotropic conductive layer 304 can be set by magnetizing one or more of the bridge pads 308A, 308B, 308C, 308D and/or the cavity pads 312A, 312B, 312C, 312D. In some examples, if the anisotropic conductive layer 304 includes the conductive particles 500, the anisotropic conductive layer 304 can be set by applying a compressive force to the interconnect bridge 302 (e.g., the compressive force 516 of FIG. 5B, etc.). The point of fabrication after completion of block 728 corresponds to the structure of the twelfth intermediate stage 634 of FIG. 6L. The operations 700 end.

Although the example operations 700 are described with reference to the flowchart illustrated in FIG. 7, many other methods of assembling the first assembly 300 of FIG. 3A and/or the second assembly 316 of FIG. 3B disclosed herein may alternatively be used. For example, the order of execution of the blocks may be changed.

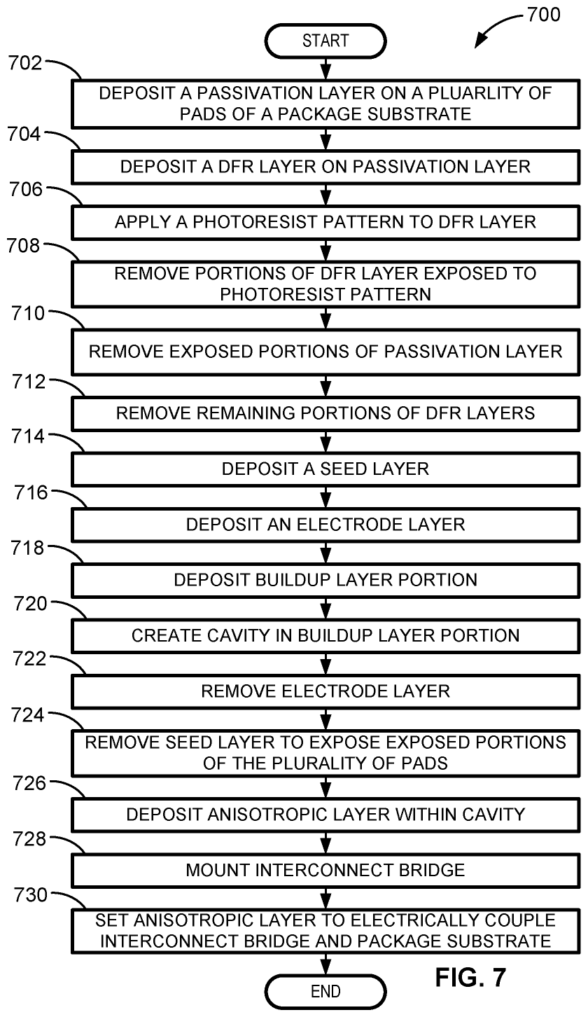

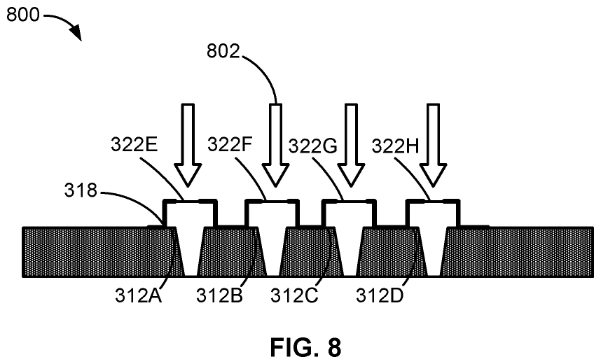

FIG. 8 depicts an example first alternative intermediate stage 800 in an example process to manufacture the second assembly 316 of FIG. 3B. The first alternative intermediate stage 800 of FIG. 8 can be used in place of the intermediate stages of FIGS. 6B, 6C, and 6D and in conjunction with the intermediate stages of FIGS. 6A and 6E-6L. Example operations to manufacture the first assembly 300 of FIG. 3A and/or the second assembly 316 of FIG. 3B via the intermediate stages of FIGS. 6A, 6E-6L and 8A are described below in conjunction with FIG. 9.

The first alternative intermediate stage 800 can occur between the first intermediate stage 600 of FIG. 6A and the fifth intermediate stage 614 of FIG. 6E. In the illustrated example of FIG. 6E, portions of the first passivation layer 318 have been removed via an example planarization 802, which exposes the exposed surfaces 322E, 322F, 322G, 322H of the cavity pads 312A, 312B, 312C, 312D. In some examples, the planarization 802 can be performed via chemical mechanical polishing (CMP), via a mechanical tool, etc. Additionally or alternatively, the exposed surfaces 322E, 322F, 322G, 322H can be exposed via laser skiving (e.g., laser beam machining, etc.). Unlike the intermediate stages 604, 608, 612 of FIGS. 6B-6D, the removal of the first passivation layer 318 occurs within the deposition of a photoresist layer and/or lithography. In some examples, the first alternative intermediate stage 800 can be performed faster than the intermediate stages 604, 608, 612 of FIGS. 6B-6D. In some examples, the planarization 802 can result in a rougher surface finish on the cavity pads 312A, 312B, 312C, 312D than the intermediate stages 604, 608, 612 of FIGS. 6B-6D.

FIG. 9 is a block diagram of another example manufacturing process for manufacturing the embedded die of FIG. 4B. The example operations 900 begin at block 902, at which the first passivation layer 318 is deposited on a plurality of pads (e.g., the cavity pads 312A, 312B, 312C, 312D, etc.) of a package substrate. For example, the block 902 can be executed in a manner similar to the execution of block 702 of FIG. 7. At block 904, the tops of the cavity pads 312A, 312B, 312C, 312D are exposed. For example, the exposed surfaces 322E, 322F, 322G, 322H of the cavity pads 312A, 312B, 312C, 312D can be exposed by removing a portion of the first passivation layer via the planarization 802 and/or via laser skiving. The point of fabrication after completion of block 904 corresponds to the structure of the first alternative intermediate stage 800 of FIG. 8. The execution of blocks 906, 908, 910, 912, 914, 916, 918, 920, 922 can be executed in a manner similar to the execution of blocks 714, 716, 718, 720, 722, 724, 726, 728, 730 of FIG. 7, respectively. In other examples, the execution of blocks 906, 908, 910, 912, 914, 916, 918, 920, 922 can be performed via any other suitable semiconductor manufacturing processes.

Although the example operations 900 are described with reference to the flowchart illustrated in FIG. 9, many other methods of assembling the first assembly 300 of FIG. 3A and/or the second assembly 316 of FIG. 3B disclosed herein may alternatively be used. For example, the order of execution of the blocks may be changed, and/or some of the blocks described may be changed, eliminated, or combined.

FIGS. 10A-10C depict a plurality of intermediate stages in an example process to deposit the example second passivation layer 320 on the interconnect bridge 302 of FIGS. 3A and 3B. It should be appreciated that other processes can be used to deposit a passivation layer on the interconnect bridge 302 of FIGS. 3A and 3B. Example operations to deposit the passivation layer 320 on the interconnect bridge 302 of FIGS. 3A and 3B via the intermediate stages of FIGS. 10A-10C are described below in conjunction with FIG. 11.

FIG. 10A is a cross-sectional schematic view of an example first intermediate stage 1000 of the deposition of the second passivation layer 320 on the interconnect bridge 302 of FIGS. 3A and 3B. The first intermediate stage 1000 occurs after the manufacturing the components of the interconnect bridge 302 (e.g., the dies, the connections, the substrate, etc.) and the formation of the bridge pads 308A, 308B, 308C, 308D. In the illustrated example of FIG. 10A, the example second passivation layer 320 has been deposited on an example bottom surface 1002 and the bridge pads 308A, 308B, 308C, 308D. For example, the second passivation layer 320 can be deposited via a thin film deposition (TFD) technique, etc. Additionally or alternatively, the second passivation layer 320 can be deposited via any other suitable deposition method (e.g., electroplating, atomic layer deposition (ALD), chemical vapor deposition (CVD), physical vapor deposition (PVD), etc.). In the illustrated example of FIG. 10A, the second passivation layer 320 is deposited as a thin film (e.g., a die backside film, etc.) with equal thickness along the bottom surface 1002, the outer facing surfaces of the bridge pads 308A, 308B, 308C, 308D, and the sides of the bridge pads 308A, 308B, 308C, 308D.

FIG. 10B is a cross-sectional schematic view of an example second intermediate stage 1004 of the deposition of the second passivation layer 320 on the interconnect bridge 302 of FIGS. 3A and 3B. In some examples, the second intermediate stage 1004 occurs after the first intermediate stage 1000 of FIG. 10A. In the illustrated example of FIG. 10B, portions of the second passivation layer 320 have been removed via an example planarization 1006, which exposes the exposed surfaces 322A, 322B, 322C, 322D of the cavity pads 312A, 312B, 312C, 312D. In some examples, the planarization 1006 can be performed via chemical mechanical polishing (CMP), via a mechanical tool, etc. Additionally or alternatively, the exposed surfaces 322A, 322B, 322C, 322D of the bridge pads 308A, 308B, 308C, 308D can be exposed via laser skiving (e.g., laser beam machining, etc.). Additionally or alternatively, the exposed surfaces 322A, 322B, 322C, 322D of the bridge pads 308A, 308B, 308C, 308D can be exposed via lithography. In some examples, an anisotropic conductive layer can be deposited on the interconnect bridge 302 after the second intermediate stage 1004. For example, an anisotropic conductive layer can be deposited on the exposed surfaces 322A, 322B, 322C, 322D of the bridge pads 308A, 308B, 308C, 308D as a die backside film. An example interconnect bridge including a backside anisotropic conductive layer is described below in conjunction with FIG. 12.

FIG. 10C is a cross-sectional schematic view of an example third intermediate stage 1008 of the deposition of the second passivation layer 320 on the interconnect bridge 302 of FIGS. 3A and 3B. In the illustrated example of FIG. 10C, the interconnect bridge 302 has been flipped (e.g., rotated 180 degrees, etc.). In some examples, the flipping of the interconnect bridge 302 is to prepare for the mounting of the interconnect bridge 302 within the cavity 306 (e.g., via a flip-chip connection, etc.).

FIG. 11 is a block diagram of an example manufacturing process for depositing the second passivation layer 320 on the interconnect bridge 302 of FIG. 3A. The example operations 1100 begin at block 1102, at which the second passivation layer 320 is deposited on a plurality of bridge pads of an interconnect bridge 302. For example, the second passivation layer 320 can be deposited via a thin film deposition (TFD) technique, etc. Additionally or alternatively, the second passivation layer 320 can be deposited via any other suitable deposition method (e.g., electroplating, atomic layer deposition (ALD), chemical vapor deposition (CVD), physical vapor deposition (PVD), etc.). At block 1104, the outer facing surfaces of the bridge pads 308A, 308B, 308C, 308D are exposed. For example, the exposed surfaces 322A, 322B, 322C, 322D of the bridge pads 308A, 308B, 308C, 308D can be exposed by removing a portion of the second passivation layer 320 via the planarization 1006 and/or via laser skiving. The point of fabrication after completion of block 1104 corresponds to the structure of the second intermediate stage 1004 of FIG. 10B. At block 1106, the interconnect bridge 302 is flipped. For example, the interconnect bridge 302 can be rotated 180 degrees to prepare for mounting in the cavity 306 of FIGS. 3A and 3B of the package substrate 110. The point of fabrication after completion of block 1106 corresponds to the structure of the third intermediate stage 1008 of FIG. 10C.

Although the example operations 1100 are described with reference to the flowchart illustrated in FIG. 11, many other methods of depositing the second passivation layer 320 on the interconnect bridge 302 of FIGS. 3A and 3B disclosed herein may alternatively be used. For example, the order of execution of the blocks may be changed, and/or some of the blocks described may be changed, eliminated, or combined.

FIG. 12 is a cross-sectional schematic view of an example mounting 1200 of another example interconnect bridge 1202 within an example cavity 306 of FIG. 3A of the example package substrate 110 of FIG. 1. In the illustrated example of FIG. 12, the package substrate 110 includes the example cavity pads 312A, 312B, 312C, 312D of FIG. 3A. The example interconnect bridge 1202 includes an example first bridge pad 1204A, an example second bridge pad 1204B, an example third bridge pad 1204C, and an example fourth bridge pad 1204D. The example bridge pads 1204A, 1204B, 1204C, 1204D are similar to the bridge pads 308A, 308B, 308C, 308D of FIGS. 3A and 3B, respectively. The example interconnect bridge 1202 is similar to the interconnect bridge 302 of FIG. 3A and FIG. 3B except that an example anisotropic conduction layer 1206 is disposed on the example bridge pads 1204A, 1204B, 1204C, 1204D prior to the mounting 1200. In some examples, the interconnect bridge 1202 can be manufactured via a process similar to the operations 1100 of FIG. 11. The anisotropic conductive layer 1206 is similar to the anisotropic conduction layer 304, except the anisotropic conductive layer 1206 is deposited as a solid and/or an adhesive liquid on the bridge pads 1204A, 1204B, 1204C, 1204D prior to the mounting 1200. In some examples, the anisotropic conductive layer 1206 is an anisotropic conductive film (AFC). In some examples, the anisotropic conductive layer 1206 is a die backside film (DBF). In some examples, the anisotropic conductive layer 1206 can be set in a manner similar to the anisotropic conductive layer 304 of FIG. 3A (e.g., via the execution of block 728, etc.). While the interconnect bridge 1202 and the cavity 306 do not include passivation layers in the illustrated example of FIG. 12, in other examples, the interconnect bridge 1202 and/or the cavity 306 can include passivation layers similar to the passivation layers 318, 320 of FIG. 3B.

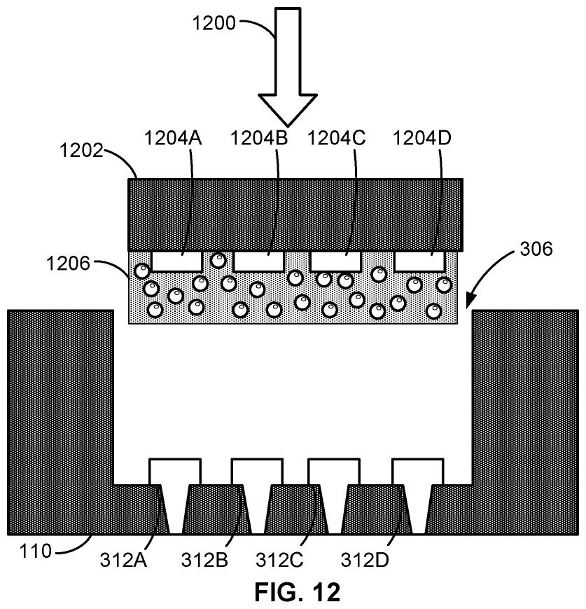

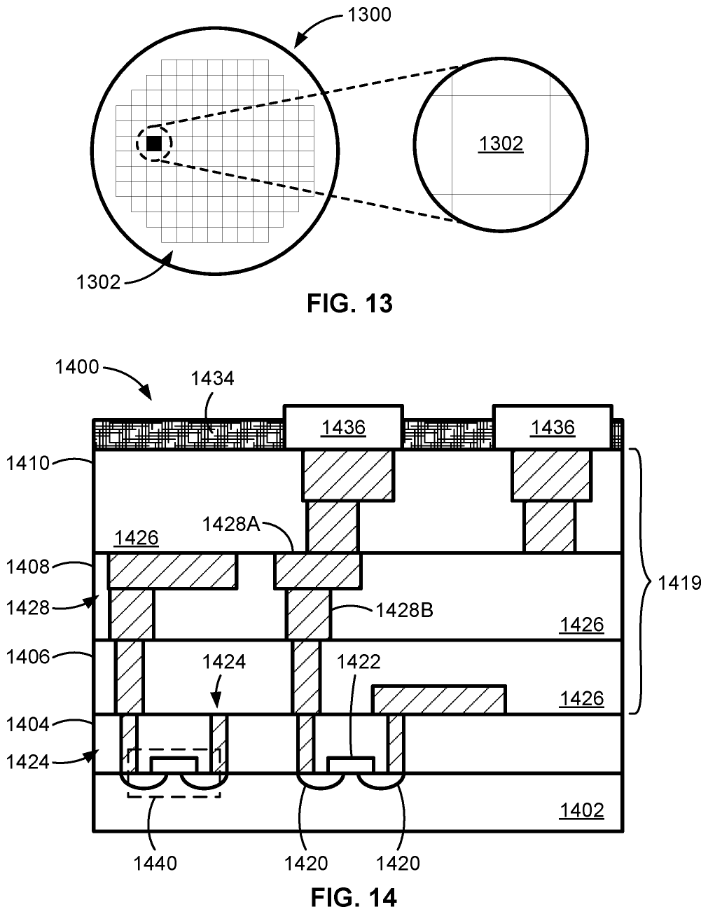

FIG. 13 is a top view of an example wafer 1300 and dies 1302 that may be included in the IC package 100 (e.g., as any suitable ones of the dies 106, 108 and/or the interconnect bridge 128). The wafer 1300 may be composed of semiconductor material and may include one or more dies 1302 having circuitry. Some or all of the dies 1302 may be a repeating unit of a semiconductor product. After the fabrication of the semiconductor product is complete, the wafer 1300 may undergo a singulation process in which the dies 1302 are separated from one another to provide discrete “chips.” One or more of the dies 1302 may include one or more transistors (e.g., some of the transistors 1440 of FIG. 14, discussed below), supporting circuitry to route electrical signals to the transistors, passive components (e.g., traces, resistors, capacitors, inductors, and/or other circuitry), and/or any other components. In some examples, the dies 1302 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry. Multiple ones of these devices may be combined on a single die (e.g., a die of the dies 1302 of FIG. 13, etc.). For example, a memory array formed by multiple memory circuits may be formed on a same die (e.g., one of the dies 1302 of FIG. 13, etc.) as programmable circuitry or other logic circuitry. Such memory may store information for use by the programmable circuitry. The example IC package 100 disclosed herein may be manufactured using a die-to-wafer assembly technique in which some dies 106, 108 and/or the interconnect bridge 128 are attached to a wafer 1300 that include others of the dies 106, 108 and/or the interconnect bridge 128, and the wafer 1300 is subsequently singulated.

FIG. 14 is a cross-sectional side view of an example IC device 1400 that may be included in the example IC package 100 (e.g., in any one of the dies 106, 108 and/or the interconnect bridge 128). One or more of the IC devices 1400 may be included in one or more dies 1302 (FIG. 13). The IC device 1400 may be formed on an example die substrate 1402 (e.g., the wafer 1300 of FIG. 13) and may be included in a die (e.g., a die of the dies 1302 of FIG. 13). The die substrate 1402 may be a semiconductor substrate composed of semiconductor material systems including, for example, n-type or p-type materials systems (or a combination of both). The die substrate 1402 may include, for example, a crystalline substrate formed using a bulk silicon or a silicon-on-insulator (SOI) substructure. In some examples, the die substrate 1402 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 1402. Although a few examples of materials from which the die substrate 1402 may be formed are described here, any material that may serve as a foundation for an IC device 1400 may be used. The die substrate 1402 may be part of a singulated die (e.g., the dies 1302 of FIG. 13) or a wafer (e.g., the wafer 1300 of FIG. 13).

The IC device 1400 may include one or more example device layers 1404 disposed on or above the die substrate 1402. The device layer 1404 may include features of one or more example transistors 1440 (e.g., metal oxide semiconductor field-effect transistors (MOSFETs)) formed on the die substrate 1402. The device layer 1404 may include, for example, one or more example source and/or drain (S/D) regions 1420, an example gate 1422 to control current flow between the S/D regions 1420, and one or more example S/D contacts 1424 to route electrical signals to/from the S/D regions 1420. The transistors 1440 may include additional features not depicted for the sake of clarity such as, for example, device isolation regions, gate contacts, and the like. The transistors 1440 are not limited to the type and configuration depicted in FIG. 14 and may include a wide variety of other types and/or configurations such as, for example, planar transistors, non-planar transistors, or a combination of both. Non-planar transistors may include FinFET transistors such as for example, double-gate transistors, tri-gate transistors, wrap-around gate transistor, and/or all-around gate transistors, such as nanoribbon and/or nanowire transistors.

Some or all of the transistors 1440 may include an example gate 1422 formed of at least two layers including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1440 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included for other purposes, such as, for example, a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1440 along the source-channel-drain direction, the gate electrode may include a U-shaped structure that includes a bottom portion substantially parallel to the surface of the die substrate 1402 and two sidewall portions that are substantially perpendicular to the top surface of the die substrate 1402. In other examples, at least one of the metal layers that form the gate electrode may be a planar layer that is substantially parallel to the top surface of the die substrate 1402 and does not include sidewall portions substantially perpendicular to the top surface of the die substrate 1402. In other examples, the gate electrode may include a combination of U-shaped structures and planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers include deposition and etching process steps. In some examples, a plurality of spacer pairs may be used; for instance, two pairs, three pairs, or four pairs of sidewall spacers may be formed on opposing sides of the gate stack.

The S/D regions 1420 may be formed within the die substrate 1402 adjacent to the gate 1422 of respective ones of the transistors 1440. The S/D regions 1420 may be formed using an implantation/diffusion process or an etching/deposition process, for example. In the former process, dopants such as boron, aluminum, antimony, phosphorous, or arsenic may be ion-implanted into the die substrate 1402 to form the S/D regions 1420. An annealing process that activates the dopants and causes the dopants to diffuse farther into the die substrate 1402 may follow the ion-implantation process. In the latter process, the die substrate 1402 may first be etched to form recesses at the locations of the S/D regions 1420. An epitaxial deposition process may then be carried out to fill the recesses with material that is used to fabricate the S/D regions 1420. In some implementations, the S/D regions 1420 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1420 may be formed using one or more alternate semiconductor materials such as germanium or a group III-V material or alloy. In further examples, one or more layers of metal and/or metal alloys may be used to form the S/D regions 1420.

Electrical signals, such as power and/or input/output (I/O) signals, may be routed to and/or from the devices (e.g., transistors 1440) of the device layer 1404 through one or more example interconnect layers disposed on the device layer 1404 (illustrated in FIG. 14 as interconnect layers 1406-1410). For example, electrically conductive features of the device layer 1404 (e.g., the gate 1422 and the S/D contacts 1424) may be electrically coupled with example interconnect structures 1428 of the interconnect layers 1406-1410. The one or more interconnect layers 1406-1410 may form an example metallization stack (also referred to as an “ILD stack”) 1419 of the IC device 1400.

The interconnect structures 1428 may be arranged within the interconnect layers 1406-1410 to route electrical signals according to a wide variety of designs (in particular, the arrangement is not limited to the particular configuration of interconnect structures 1428 depicted in FIG. 14). Although a particular number of interconnect layers 1406-1410 is depicted in FIG. 14, examples of the present disclosure include IC devices having more or fewer interconnect layers than depicted.

In some examples, the interconnect structures 1428 may include example lines 1428A and/or example vias 1428B filled with an electrically conductive material such as a metal. The lines 1428A may be arranged to route electrical signals in a direction of a plane that is substantially parallel with a surface of the die substrate 1402 upon which the device layer 1404 is formed. For example, the lines 1428A may route electrical signals in a direction in and out of the page from the perspective of FIG. 14. The vias 1428B may be arranged to route electrical signals in a direction of a plane that is substantially perpendicular to the surface of the die substrate 1402 upon which the device layer 1404 is formed. In some examples, the vias 1428B may electrically couple lines 1428A of different interconnect layers 1406-1410 together.

The interconnect layers 1406-1410 may include an example dielectric material 1426 disposed between the interconnect structures 1428, as shown in FIG. 14. In some examples, the dielectric material 1426 disposed between the interconnect structures 1428 in different ones of the interconnect layers 1406-1410 may have different compositions. In other examples, the composition of the dielectric material 1426 between different interconnect layers 1406-1410 may be the same.

A first interconnect layer 1406 (referred to as Metal 1 or “M1”) may be formed directly on the device layer 1404. In some examples, the first interconnect layer 1406 may include lines 1428A and/or vias 1428B, as shown. The lines 1428A of the first interconnect layer 1406 may be coupled with contacts (e.g., the S/D contacts 1424) of the device layer 1404.

A second interconnect layer 1408 (referred to as Metal 2 or “M2”) may be formed directly on the first interconnect layer 1406. In some examples, the second interconnect layer 1408 may include vias 1428B to couple the lines 1428A of the second interconnect layer 1408 with the lines 1428A of the first interconnect layer 1406. Although the lines 1428A and the vias 1428B are structurally delineated with a line within each interconnect layer (e.g., within the second interconnect layer 1408) for the sake of clarity, the lines 1428A and the vias 1428B may be structurally and/or materially contiguous (e.g., simultaneously filled during a dual-damascene process) in some examples.

A third interconnect layer 1410 (referred to as Metal 3 or “M3”) (and additional interconnect layers, as desired) may be formed in succession on the second interconnect layer 1408 according to similar techniques and configurations described in connection with the second interconnect layer 1408 and/or the first interconnect layer 1406. In some examples, the interconnect layers that are “higher up” in the metallization stack 1419 in the IC device 1400 (i.e., further away from the device layer 1404) may be thicker.

The IC device 1400 may include an example solder resist material 1434 (e.g., polyimide or similar material) and one or more example conductive contacts 1436 formed on the interconnect layers 1406-1410. In FIG. 14, the conductive contacts 1436 are illustrated as taking the form of bond pads. The conductive contacts 1436 may be electrically coupled with the interconnect structures 1428 and configured to route the electrical signals of the transistor(s) 1440 to other external devices. For example, solder bonds may be formed on the one or more conductive contacts 1436 to mechanically and/or electrically couple a chip including the IC device 1400 with another component (e.g., a circuit board). The IC device 1400 may include additional or alternate structures to route the electrical signals from the interconnect layers 1406-1410; for example, the conductive contacts 1436 may include other analogous features (e.g., posts) that route the electrical signals to external components.

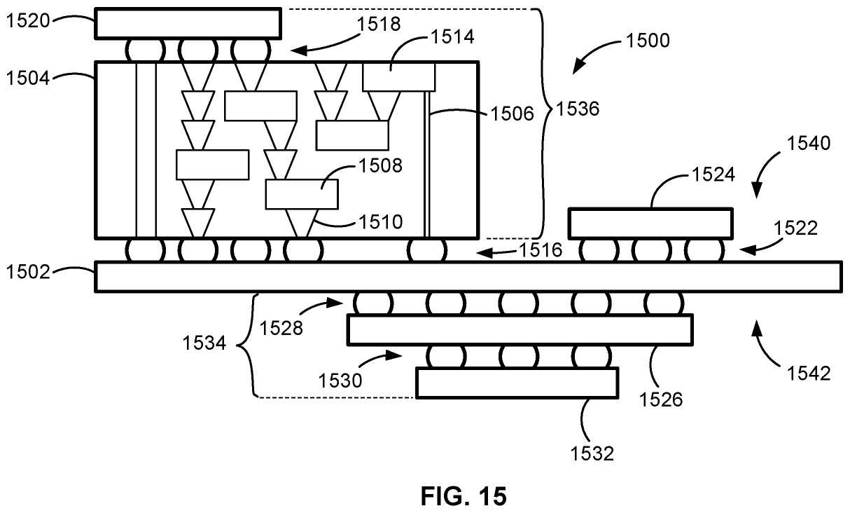

FIG. 15 is a cross-sectional side view of an example IC device assembly 1500 that may include the IC package 100 disclosed herein. In some examples, the IC device assembly corresponds to the IC package 100. The IC device assembly 1500 includes a number of components disposed on an example circuit board 1502 (which may be, for example, a motherboard). The IC device assembly 1500 includes components disposed on an example first face 1540 of the circuit board 1502 and an example opposing second face 1542 of the circuit board 1502. Any of the IC packages discussed herein with reference to the IC device assembly 1500 may take the form of the example IC package 100.

In some examples, the circuit board 1502 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1502. In other examples, the circuit board 1502 may be a non-PCB substrate. In some examples, the circuit board 1502 may be, for example, the circuit board 102 of FIG. 1.

The IC device assembly 1500 illustrated in FIG. 15 includes an example package-on-interposer structure 1536 coupled to the first face 1540 of the circuit board 1502 by example coupling components 1516. The coupling components 1516 may electrically and mechanically couple the package-on-interposer structure 1536 to the circuit board 1502, and may include solder balls (as shown in FIG. 15), male and female portions of a socket, an adhesive, an underfill material, and/or any other suitable electrical, chemical, and/or mechanical coupling structure.

The package-on-interposer structure 1536 may include an example IC package 1520 coupled to an example interposer 1504 by example coupling components 1518. The coupling components 1518 may take any suitable form for the application, such as the forms discussed above with reference to the coupling components 1516. Although a single IC package 1520 is shown in FIG. 15, multiple IC packages may be coupled to the interposer 1504. Additionally or alternatively, in some examples, additional interposers may be coupled to the interposer 1504. The interposer 1504 may provide an intervening substrate used to bridge the circuit board 1502 and the IC package 1520. The IC package 1520 may be or include, for example, a die (e.g., a die of the dies 1302 of the dies of FIG. 13), an IC device (e.g., the IC device 1400 of FIG. 14), and/or any other suitable component(s). Generally, the interposer 1504 may spread a connection to a wider pitch or reroute a connection to a different connection. For example, the interposer 1504 may couple the IC package 1520 (e.g., a die) to a set of BGA conductive contacts of the coupling components 1516 for coupling to the circuit board 1502. In the example illustrated in FIG. 15, the IC package 1520 and the circuit board 1502 are attached to opposing sides of the interposer 1504. In other examples, the IC package 1520 and the circuit board 1502 may be attached to a same side of the interposer 1504. In some examples, three or more components may be interconnected by way of the interposer 1504.

In some examples, the interposer 1504 may be formed as a PCB, including multiple metal layers separated from one another by layers of dielectric material and interconnected by electrically conductive vias. In some examples, the interposer 1504 may be formed of an epoxy resin, a fiberglass-reinforced epoxy resin, an epoxy resin with inorganic fillers, a ceramic material, or a polymer material such as polyimide. In some examples, the interposer 1504 may be formed of alternate rigid or flexible materials that may include the same materials described above for use in a semiconductor substrate, such as silicon, germanium, and other group III-V and group IV materials. The interposer 1504 may include example metal interconnects 1508 and example vias 1510, including but not limited to example through-silicon vias (TSVs) 1506. The interposer 1504 may further include example embedded devices 1514, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1504. The package-on-interposer structure 1536 may take the form of any of the package-on-interposer structures known in the art.

The IC device assembly 1500 may include an example IC package 1524 coupled to the first face 1540 of the circuit board 1502 by example coupling components 1522. The coupling components 1522 may take the form of any of the examples discussed above with reference to the coupling components 1516, and the IC package 1524 may take the form of any of the examples discussed above with reference to the IC package 1520.

The IC device assembly 1500 illustrated in FIG. 15 includes an example package-on-package structure 1534 coupled to the second face 1542 of the circuit board 1502 by coupling components 1528. The package-on-package structure 1534 may include a first example IC package 1526 and a second example IC package 1532 coupled together by example coupling components 1530 such that the first IC package 1526 is disposed between the circuit board 1502 and the second IC package 1532. The coupling components 1528, 1530 may take the form of any of the examples of the coupling components 1516 discussed above, and the IC packages 1526, 1532 may take the form of any of the examples of the IC package 1520 discussed above.

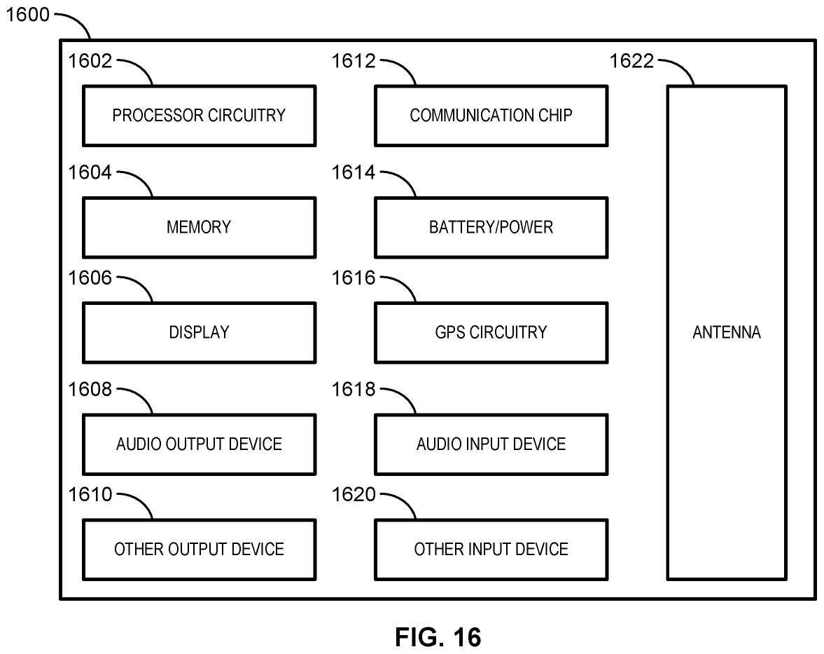

FIG. 16 is a block diagram of an example electrical device 1600 that may include one or more of the example IC package 100. For example, any suitable ones of the components of the electrical device 1600 may include one or more of the device assemblies 1500, IC devices 1400, or dies 1302 disclosed herein, and may be arranged in the example IC package 100. A number of components are illustrated in FIG. 16 as included in the electrical device 1600, but any one or more of these components may be omitted or duplicated, as suitable for the application. In some examples, some or all of the components included in the electrical device 1600 may be attached to one or more motherboards. In some examples, some or all of these components are fabricated onto a single system-on-a-chip (SoC) die.

Additionally, in some examples, the electrical device 1600 may not include one or more of the components illustrated in FIG. 16, but the electrical device 1600 may include interface circuitry for coupling to the one or more components. For example, the electrical device 1600 may not include an example display 1606, but may include display interface circuitry (e.g., a connector and driver circuitry) to which the display 1606 may be coupled. In some examples, the electrical device 1600 may not include an example audio input device 1618 (e.g., microphone) or an example audio output device 1608 (e.g., a speaker, a headset, earbuds, etc.), but may include audio input or output device interface circuitry (e.g., connectors and supporting circuitry) to which the audio input device 1618 or the audio output device 1608 may be coupled.

The electrical device 1600 may include example programmable or processor circuitry 1602 (e.g., one or more processing devices). The processor circuitry 1602 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices.

The electrical device 1600 may include an example memory 1604, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1604 may include memory that shares a die with the processor circuitry 1602. This memory may be used as cache memory and may include embedded dynamic random access memory (eDRAM) or spin transfer torque magnetic random access memory (STT-MRAM).

In some examples, the electrical device 1600 may include an example communication chip 1612 (e.g., one or more communication chips). For example, the communication chip 1612 may be configured for managing wireless communications for the transfer of data to and from the electrical device 1600. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1612 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1612 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1612 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1612 may operate in accordance with other wireless protocols in other examples. The electrical device 1600 may include an example antenna 1622 to facilitate wireless communications and/or to receive other wireless communications (such as AM or FM radio transmissions).

In some examples, the communication chip 1612 may manage wired communications, such as electrical, optical, or any other suitable communication protocols (e.g., the Ethernet). As noted above, the communication chip 1612 may include multiple communication chips. For instance, a first communication chip 1612 may be dedicated to shorter-range wireless communications such as Wi-Fi or Bluetooth, and a second communication chip 1612 may be dedicated to longer-range wireless communications such as global positioning system (GPS), EDGE, GPRS, CDMA, WiMAX, LTE, EV-DO, or others. In some examples, a first communication chip 1612 may be dedicated to wireless communications, and a second communication chip 1612 may be dedicated to wired communications.

The electrical device 1600 may include example battery/power circuitry 1614. The battery/power circuitry 1614 may include one or more energy storage devices (e.g., batteries or capacitors) and/or circuitry for coupling components of the electrical device 1600 to an energy source separate from the electrical device 1600 (e.g., AC line power).

The electrical device 1600 may include the display 1606 (or corresponding interface circuitry, as discussed above). The display 1606 may include any visual indicators, such as a heads-up display, a computer monitor, a projector, a touchscreen display, a liquid crystal display (LCD), a light-emitting diode display, or a flat panel display.

The electrical device 1600 may include the audio output device 1608 (or corresponding interface circuitry, as discussed above). The audio output device 1608 may include any device that generates an audible indicator, such as speakers, headsets, or earbuds.

The electrical device 1600 may include the audio input device 1618 (or corresponding interface circuitry, as discussed above). The audio input device 1618 may include any device that generates a signal representative of a sound, such as microphones, microphone arrays, or digital instruments (e.g., instruments having a musical instrument digital interface (MIDI) output).

The electrical device 1600 may include example GPS circuitry 1616. The GPS circuitry 1616 may be in communication with a satellite-based system and may receive a location of the electrical device 1600, as known in the art.

The electrical device 1600 may include any other example output device 1610 (or corresponding interface circuitry, as discussed above). Examples of the other output device 1610 may include an audio codec, a video codec, a printer, a wired or wireless transmitter for providing information to other devices, and/or an additional storage device.

The electrical device 1600 may include any other example input device 1620 (or corresponding interface circuitry, as discussed above). Examples of the other input device 1620 may include an accelerometer, a gyroscope, a compass, an image capture device, a keyboard, a cursor control device such as a mouse, a stylus, a touchpad, a bar code reader, a Quick Response (QR) code reader, any sensor, and/or a radio frequency identification (RFID) reader.

The electrical device 1600 may have any desired form factor, such as, for example, a hand-held or mobile electrical device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device (e.g., a smartwatch, a ring, googles, a headset, glasses, etc.). In some examples, the electrical device 1600 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. In some examples described herein, components are described with reference to a vertical, horizontal, and lateral axes. As used herein, the term “vertical” refers to a direction perpendicular to the plane of the substrate on which the IC package is fabricated. As used herein the terms “horizontal” and “lateral” perpendicular to the vertical axis. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

In some examples used herein, the term “substantially” is used to describe a geometric relationship between two parts that is within three degrees of the stated relationship (e.g., a substantially colinear relationship is within three degrees of being linear, a substantially perpendicular relationship is within three degrees of being perpendicular, a substantially parallel relationship is within three degrees of being parallel, etc.).

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

Anisotropic conductive connections for interconnect bridges and related methods. Further examples and combinations thereof include the following:

Example 1 includes a package substrate for an integrated circuit package, the package substrate comprising a first pad disposed at a first end of an interconnect within the package substrate, the first pad disposed in a cavity in the package substrate, an interconnect bridge disposed in the cavity, the interconnect bridge including a second pad, and a third pad, and a layer disposed between the first pad and the second pad, the layer having a first conductivity between the first pad and the second pad, the layer having a second conductivity between the second pad and the third pad, the first conductivity greater than the second conductivity.

Example 2 includes the package substrate of example 1, wherein the layer is composed of conductive particles supported by a nonconductive polymer matrix.

Example 3 includes the package substrate of example 2, wherein the conductive particles have a first density between the first pad and the second pad, the conductive particles have a second density between the second pad and the third pad, and the first density is greater than the second density.

Example 4 includes the package substrate of example 2, wherein the conductive particles include at least one of gold particles, silver particles, nickel particles, and silver-nickel alloy particles.

Example 5 includes the package substrate of example 1, wherein the layer is an anisotropic conductive layer, and the package substrate further includes a first passivation layer disposed between the first pad and the layer.

Example 6 includes the package substrate of example 5, further including a second passivation layer disposed between the layer and at least one of the second or third pads.

Example 7 includes the package substrate of example 1, wherein the layer includes a multilayer particle including a polymer core, a metal coating abutting the polymer core, and a polymer coating abutting the metal coating.

Example 8 includes the package substrate of example 1, wherein the layer is an anisotropic conductive film.

Example 9 includes an integrated circuit package comprising a package substrate supporting a semiconductor die, the package substrate including a first contact pad, an interconnect bridge positioned within a cavity of the package substrate, the interconnect bridge including a second contact pad, and an anisotropic conductive layer disposed between the first contact pad and the second contact pad, the anisotropic conductive layer electrically coupling the package substrate and interconnect bridge.

Example 10 includes the integrated circuit package of example 9, wherein the anisotropic conductive layer includes a nonconductive substrate, and a plurality of conductive particles suspended in the nonconductive substrate.

Example 11 includes the integrated circuit package of example 9, further including a plurality of cavity pads disposed at a bottom surface of the cavity, the plurality of cavity pads including the first contact pad, and a plurality of bridge pads coupled to the interconnect bridge, the plurality of bridge pads including the second contact pad, ones of the plurality of bridge pads aligned with and electrically coupled to via the anisotropic conductive layer, to corresponding one of the plurality of cavity pads.

Example 12 includes the integrated circuit package of example 11, further including a passivation layer disposed between the plurality of bridge pads and the anisotropic conductive layer.

Example 13 includes the integrated circuit package of example 12, wherein the passivation layer is not disposed on an outer facing surfaces of at least one of the plurality of bridge pads.

Example 14 includes the integrated circuit package of example 11, further including a passivation layer disposed between the plurality of cavity pads and the anisotropic conductive layer.

Example 15 includes the integrated circuit package of example 9, wherein the anisotropic conductive layer includes a multilayer particle including a polymer core, a metal coating abutting the polymer core, and a polymer coating abutting the metal coating.

Example 16 includes the integrated circuit package of example 15, wherein the multilayer particle is a first multilayer particle and further including a second multilayer particle, the first multilayer particle disposed between the first contact pad and the second contact pad, the first multilayer particle having a deformed shape, the second multilayer particle having a non-deformed shape.

Example 17 includes a method comprising depositing an anisotropic layer on at least one (1) a first pad on a bottom surface of a cavity in a package substrate or (2) an interconnect bridge, the anisotropic layer including a plurality of conductive particles, the first pad abutting a via, mounting the interconnect bridge within the cavity, the interconnect bridge having a second pad and a third pad, and setting the conductive particles to have a first conductivity between the first pad and the second pad, and a second conductivity between the second pad and the third pad, the first conductivity greater than the second conductivity.

Example 18 includes the method of example 17, wherein setting the conductive particles includes thermally curing the anisotropic layer.

Example 19 includes the method of example 17, wherein the conductive particles are multilayer particles and setting the conductive particles include applying a compressive vertical force to the interconnect bridge.

Example 20 includes the method of example 17, wherein setting the conductive particles including applying an electric charge to the first pad.

From the foregoing, it will be appreciated that example systems, apparatus, articles of manufacture, and methods have been disclosed that utilize anisotropic conductive layers to electrically couple a bridge interconnect and the through silicon vias of a package substrate. In the examples disclosed herein, the anisotropic conductive layers conducts powers and/or electrical signals between vertically aligned (e.g., interfacing pairs of, etc.) pads of the package substrate and bridge interconnect and reduces the likelihood of unwanted transmission of such between non-aligned (e.g., laterally adjacent) pads. Examples disclosed herein enable denser spacing of bride pads and cavity pads and smaller pad pitches. Examples disclosed herein reduce the likelihood of connection faults, such as tin wicking, pad misalignment, and void underfills.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A package substrate for an integrated circuit package, the package substrate comprising:
a first pad disposed at a first end of an interconnect within the package substrate, the first pad disposed in a cavity in the package substrate;
an interconnect bridge disposed in the cavity, the interconnect bridge including:
a second pad; and
a third pad; and
a layer disposed between the first pad and the second pad, the layer having a first conductivity between the first pad and the second pad, the layer having a second conductivity between the second pad and the third pad, the first conductivity greater than the second conductivity.

2. The package substrate of claim 1, wherein the layer is composed of conductive particles supported by a nonconductive polymer matrix.

3. The package substrate of claim 2, wherein the conductive particles have a first density between the first pad and the second pad, the conductive particles have a second density between the second pad and the third pad, and the first density is greater than the second density.

4. The package substrate of claim 2, wherein the conductive particles include at least one of gold particles, silver particles, nickel particles, and silver-nickel alloy particles.

5. The package substrate of claim 1, wherein the layer is an anisotropic conductive layer, and the package substrate further includes a first passivation layer disposed between the first pad and the layer.

6. The package substrate of claim 5, further including a second passivation layer disposed between the layer and at least one of the second or third pads.

7. The package substrate of claim 1, wherein the layer includes a multilayer particle including:
a polymer core;
a metal coating abutting the polymer core; and
a polymer coating abutting the metal coating.

8. The package substrate of claim 1, wherein the layer is an anisotropic conductive film.

9. An integrated circuit package comprising:
a package substrate supporting a semiconductor die, the package substrate including a first contact pad;
an interconnect bridge positioned within a cavity of the package substrate, the interconnect bridge including a second contact pad; and
an anisotropic conductive layer disposed between the first contact pad and the second contact pad, the anisotropic conductive layer electrically coupling the package substrate and interconnect bridge.

10. The integrated circuit package of claim 9, wherein the anisotropic conductive layer includes:
a nonconductive substrate; and
a plurality of conductive particles suspended in the nonconductive substrate.

11. The integrated circuit package of claim 9, further including:
a plurality of cavity pads disposed at a bottom surface of the cavity, the plurality of cavity pads including the first contact pad; and
a plurality of bridge pads coupled to the interconnect bridge, the plurality of bridge pads including the second contact pad, ones of the plurality of bridge pads aligned with and electrically coupled to via the anisotropic conductive layer, to corresponding one of the plurality of cavity pads.

12. The integrated circuit package of claim 11, further including a passivation layer disposed between the plurality of bridge pads and the anisotropic conductive layer.

13. The integrated circuit package of claim 12, wherein the passivation layer is not disposed on an outer facing surfaces of at least one of the plurality of bridge pads.

14. The integrated circuit package of claim 11, further including a passivation layer disposed between the plurality of cavity pads and the anisotropic conductive layer.

15. The integrated circuit package of claim 9, wherein the anisotropic conductive layer includes a multilayer particle including:
a polymer core;
a metal coating abutting the polymer core; and
a polymer coating abutting the metal coating.

16. The integrated circuit package of claim 15, wherein the multilayer particle is a first multilayer particle and further including a second multilayer particle, the first multilayer particle disposed between the first contact pad and the second contact pad, the first multilayer particle having a deformed shape, the second multilayer particle having a non-deformed shape.

17. A method comprising:
depositing an anisotropic layer on at least one (1) a first pad on a bottom surface of a cavity in a package substrate or (2) an interconnect bridge, the anisotropic layer including a plurality of conductive particles, the first pad abutting a via;
mounting the interconnect bridge within the cavity, the interconnect bridge having a second pad and a third pad; and
setting the conductive particles to have a first conductivity between the first pad and the second pad, and a second conductivity between the second pad and the third pad, the first conductivity greater than the second conductivity.

18. The method of claim 17, wherein setting the conductive particles includes thermally curing the anisotropic layer.

19. The method of claim 17, wherein the conductive particles are multilayer particles and setting the conductive particles include applying a compressive vertical force to the interconnect bridge.

20. The method of claim 17, wherein setting the conductive particles including applying an electric charge to the first pad.
